(19) United States
(12) Patent Application Publication
(10) Pub. No.: US 2022/0207211 A1
(43) Pub. Date: Jun. 30, 2022

(54) VOID SPACE DOMAIN DECOMPOSITION FOR SIMULATION OF PHYSICAL PROCESSES

(71) Applicant: Thomas Wetteland BAEHR-JONES, Arcadia, CA (US)

(72) Inventor: Thomas Wetteland BAEHR-JONES, Arcadia, CA (US)

(21) Appl. No.: 17/274,786

(22) PCT Filed: Aug. 12, 2020
(86) PCT No.: PCT/US2020/045889

§ 371 Date: Mar. 10, 2021

Related U.S. Application Data
(63) Continuation of application No. 16/543,109, filed on Aug. 16, 2019.

(51) Int. Cl. G06F 30/23; G06F 17/12

(52) U.S. Cl. CPC G06F 30/23; G06F 17/12

(57) ABSTRACT

Systems and methods for computer simulation for determining a field generated from a source, with the field interacting with one or more structures. The systems and methods comprise dividing a domain into subdomains, solving iteratively for the field in a subset of the subdomains by solving for a residual field within an extended subdomain around each subdomain within the subset. If the subdomain comprises a structure, the boundary of the structure extends beyond the boundary of the extended subdomain to a second extended subdomain.

### TECHNICAL FIELD

This disclosure relates generally to the field of computer simulation. In particular, it relates to domain decomposition.

### BACKGROUND

In the art of mathematical modeling or simulation of physical objects or physical fields, there are a few basic methods used to solve partial differential equations important in science and engineering. Maxwell's equations, the stress-strain equations, heat transfer equations and fluid flow differential equations all have a certain similarity in that exact solutions, in either the time domain, frequency domain, or static case, cannot be found for many situations of interest. What one typically does is to convert the continuous fields or other physical quantities of interest into a set of relatively uniform spaced points (finite-difference methods) or more general triangle or tetrahedra shapes (finite-element methods), and thereby convert the partial differential equations of interest into a set of discrete (usually linear) equations. These linear equations can then be solved or iterated using a computer, thereby providing an approximate solution for the original partial differential equations for a domain and set of structures of interest.

Both finite-difference and finite-element approaches usually involve the generation of a matrix equation with a very large number of variables. The number of variables might be in excess of tens of millions or even more. Each variable typically corresponds to the force, electromagnetic field, voltage, or other physical attribute at a point in the model or the simulation. Furthermore, boundary conditions are typically imposed on the points appearing at the edges of the physical model or simulation domain, and possibly elsewhere as well in the case of other constraints. These matrix equations are then solved by any one of a number of methods: in some cases, the matrix equation can be solved directly, or in some cases an iterative approach can be used. Preconditioners can also be used, which are mathematical techniques used to speed up conversion for iterative matrix solvers. In all cases, solving larger matrix equations becomes increasingly difficult for larger numbers of variables, fundamentally limiting the domain size that can be used and the speed with which the computation can proceed. Further, multiple copies of the solution vector usually need to be stored, which also makes it harder to use larger numbers of variables, and hence finite-difference or finite-element values.

In the art of mathematical modeling or simulation of physical objects or physical fields, there are a few methods that do not require the solution of a linear matrix equation. One example is the finite-difference time domain (FDTD) method. This method is one of only a few that has the property that it does not require a matrix solution to advance the solution vector by a small time increment. In fact, only a single copy of the solution vector even needs to be stored in memory. However, the FDTD method does not directly provide a steady-state solution, which is usually more useful than a time domain solution. One can usually recover an approximate steady-state solution of acceptable accuracy by performing time domain Fourier filtering of the FDTD solution. This approach—FDTD combined with Fourier filtering—is the state of the art for design approaches used in much of the optics regime. Despite the lack of a steady-state solution, FDTD is preferred to finite-element because FDTD does not require a solution of a matrix equation, thereby vastly increasing the number of points that can be used in a simulation. In the optics regime, many simulations of interest require the accurate modeling of the dispersion relations of radiation in a given region. The needed accuracy can only be obtained by using a sufficient number of points, hence the preference for FDTD in the optics regime. For some radiofrequency (RF) regime problems, similar considerations lead FDTD to be preferred, but more often finite-element is used as the wavelengths involved are usually much longer compared to the structure sizes.

It is worth noting that if one has a steady-state solution, nonlinearities in the system can sometimes be dealt with by using a succession of steady-state solutions, in which the nonlinear portion of the underlying partial differential equation can be used as a linear “stimulus” term. Repeating the solution until self-consistency is obtained can then provide a solution of arbitrary accuracy for even notoriously difficult-to-solve nonlinear partial differential equations. A specific weakness of FDTD is that in many cases, it cannot practically address nonlinear problems at all. Nonlinear formulations of FDTD do exist, but typically numerical error and insufficient dynamic range often prevent FDTD from being applied successfully to nonlinear problems.

In order to address the fundamental limitation of solving steady-state problems in the optics regime, specifically the inability to scale the size of a solution vector to the size required, various domain decomposition approaches have been proposed over the years. A number of terms are used to describe these methods. One widely used term is the Iterative Multiregion (IMR) technique or method.

Publications that describe the IMR technique include Al Sharkawy et al. (Plane Wave Scattering From Three Dimensional Multiple Objects Using the Iterative Multiregion Technique Based on the FDFD Method, IEEE Transactions on Antennas and Propagation, Vol. 54, No. 2, February 2006, pages 666-672) Al Sharkawy et al. disclose an iterative approach using the finite difference frequency domain method that is presented in order to solve the problem of scattering from large three-dimensional electromagnetic scatterers. The iterative multiregion technique is introduced to divide one computational domain into smaller subregions and solve each subregion separately. Then the subregion solutions are combined iteratively to obtain a solution for the complete domain. As a result, a considerable reduction in the computation time and memory has been achieved.

Another publications that describes the IMR technique is by Fatih Kaburcuk, et al. (IMR technique for antenna and scattering problems using hybrid solutions based on the MoM and FDTD method, 2014 International Conference on Electromagnetics in Advanced Applications (ICEAA), published online at IEEE Xplore: 22 Sep. 2014, DOI: 10.1109/ICEAA.2014.6903866). Kaburcuk, et al. combine integration of the method of moments (MoM) and the finite-difference time-domain method (FDTD) into the iterative multi-region (IMR) technique. This approach leverages the advantageous features of MoM and FDTD to solve large scale antenna and scattering problems. The original problem domain is divided into unconnected sub-regions, with an appropriate method used in each subregion.

In general, the IMR technique divides the problem domain into a number of subdomains. Each subdomain is solved with an outgoing-wave absorbing boundary condition (ABC), which in some cases is a perfectly matched layer (PML). The resulting field is then converted into a source current which can be used to re-launch the field into a neighboring subdomain. The process can then be repeated on each subdomain in turn. Eventually, the true global solution will converge. A time-domain variant has also been demonstrated by Kaburcuk, et al.

In spite of these domain-decomposition methods, there are no general-purpose simulation tools that solve Maxwell's equations in the optics regime that rely on a domain-decomposition technique such as IMR. Usually, engineers solely use FDTD in the optics regime, and often FDTD or finite-element in the RF regime. There is a fundamental weakness with these domain-decomposition methods, at least as they are typically implemented.

In the case of frequency-domain domain-decomposition methods, each iteration involves the accumulation of unavoidable error from the boundary condition regions. Even if an eventual steady-state solution is obtained, the cumulative error from the boundary condition regions, which cannot be corrected for or even identified as such, often corrupts the resulting solution to the point that it is often not usable. Techniques. such as the IMR method have not been had widespread use due to the inability of these techniques to deal adequately with boundary conditions. Depending on the implementation method, there may be further types of errors injected into the eventual solution as compared to the ideal solution that would be obtained from solving the entire linear system at once. Furthermore, methods such as IMR, lack any mechanism to cope with this intrinsic source of error. Another consideration is that domain-decomposition, on its own, does not automatically speed up the solution to a problem. For example, Al Sharkawy et al. report a speedup of only a factor of 2 in solve time compared to the non-domain decomposition method—which is not very attractive considering the difficulty of implementing IMR and the added intrinsic, uncorrectable (and often undetectable) error that is then introduced into the simulation.

Time-domain domain-decomposition approaches also have this limitation, and further suffer from additional errors in the domain-stitching. The primary problem is that in contrast to frequency domain methods, there is not a single self-consistent matrix equation that can be applied to verify that, at least not including the boundary conditions, the solution is correct.

There are some simulation approaches that may be described as reduced accuracy domain-decomposition methods. For example, the fast multipole method (FMM) is used in some cases to reduce a complex electromagnetic problem into solving for a set of sub-domains, each of which can approach a simpler functional form (a monopole or dipole for example) from the perspective of the other domains. This reduction of the “linkage” between domains can simplify the problem. Variants of this method are often used in antenna design, for example. However, these methods ultimately do not give the exact discrete solutions to Maxwell's equations that FDTD or a finite-element method would provide, and so are of reduced utility in many cases.

Gibson, W. C. (The Method of Moments in Electromagnetics, 2^{nd} Edition, CRC Press, published Jul. 10, 2014 (2015), ISBN 9781482235791) describes the FMM and discloses the solution of electromagnetic integral equations via the method of moments (MOM). This disclosure derives a generalized set of surface integral equations that can be used to treat problems with conducting and dielectric regions. It further solves these integral equations for progressively more difficult problems involving thin wires, bodies of revolution, and two- and three-dimensional bodies.

U.S. Pat. No. 10,089,424 (Tarman et al) discloses systems and methods for 2D domain decomposition during parallel reservoir simulation in which balance the active cells in a reservoir model are balanced. The method comprises: calculating each combination for a predetermined number of decomposition domains in a reservoir model; identifying a number of decomposition domains in an X direction and a number of decomposition domains in a Y direction for one of the combinations; calculating one or more decomposition boundaries in a predetermined order for the number of decomposition domains in the X direction and the number of decomposition domains in the Y direction; calculating an offset size based on an ideal number of active cells for each of the predetermined number of decomposition domains and the actual number of active cells; calculating one or more decomposition boundaries in another predetermined order for the number of decomposition domains in the X direction and the number of decomposition domains in the Y direction; calculating another offset size based on the ideal number of active cells for each of the predetermined number of decomposition domains and the another actual number of active cells; repeating steps 2-6 for each combination calculated in the first step; and selecting one of the combinations with a lowest one of the offset size and the another offset size.

WO201762531 A2 (Bratvedt K et al) discloses systems, computer-readable media, and methods for performing a reservoir simulation. Reservoir data and simulation parameters are obtained, followed by determination of partial differential equations based on the simulation parameters. A timestep of the reservoir simulation is performed, based on the reservoir data and the partial differential equations by removing an effect of long coherent structures with high contrasts (e.g. fractures, faults, high and low permeability channels, or shale layers) from the partial differential equations to provide adapted partial differential equations. An algebraic multiscale method is subsequently performed on the adapted partial differential equations to generate an approximated solution.

US Pub. No. 2010/0082724 A1 (Diyankov et al) discloses a parallel-computing iterative solver that uses a preconditioner which is processed using parallel-computing for solving linear systems of equations iteratively. Examples of such equations include 3D modeling of oil or gas reservoirs. An original matrix is partitioned and transformed to a block bordered diagonal form. Furthermore, an approach for deriving a preconditioner for use in parallel iterative solution of a linear system of equations is provided. In particular, a parallel-computing iterative solver may derive and/or apply such a preconditioner for use in solving, through parallel processing, a linear system of equations.

Current approaches of using domain-decomposition do not deal adequately with the boundary error problem. Furthermore, such approaches do not provide a substantial speedup. As such, domain-decomposition methods are rarely used for obtaining practical exact discrete solutions to fundamental partial differential equations of science and engineering, including the field of electrodynamics (Maxwell's equations); the heat transfer equation, fluid flow, and the stress-strain equations. Such solutions are of immense practical value.

### BRIEF SUMMARY

In one aspect, there is disclosed a computer implemented method for determining a field generated from a source, the field interacting with one or more structures, the method comprising: providing a simulation space comprising a domain that contains the source and the one or more structures; simulating, by a computer, the field within the domain based at least in part on an operator acting on the field, with simulating further comprising: dividing the domain into a plurality of subdomains; designating a first iteration of the field; determining a global residual source based on the operator acting on the first iteration of the field throughout the domain; iteratively solving for the field by solving for residual field behavior in a subset of the subdomains at each iteration; wherein solving for residual field behavior in a subdomain of the subset comprises: the operator acting on a local residual field within an extended subdomain around the subdomain; and where the subdomain comprises a structure, extending a boundary of the structure located at a boundary of the extended subdomain, beyond the boundary of the extended subdomain to a second extended subdomain.

In another aspect, there is provided a non-transitory computer storage medium encoded with computer program instructions for determining a field generated from a source, the field interacting with one or more structures, with the computer program instructions when executed by one or more computers cause the one or more computers to: provide a simulation space comprising a domain that contains the source and the one or more structures; simulate the field within the domain based at least in part on an operator acting on the field; divide the domain into a plurality of subdomains; designate a first iteration of the field; determine a residual source based on the operator acting on the first iteration of the field throughout the domain; iteratively solve for the field by solving for residual field behavior in a subset of the subdomains; wherein solving for residual field behavior in a subdomain of the subset comprises: the operator acting on the residual field within an extended subdomain around the subdomain; and where the subdomain comprises a structure, extending a boundary of the structure located at a boundary of the extended subdomain, beyond the boundary of the extended subdomain to a second extended subdomain.

In yet another aspect, there is provided a computer system for simulating a field generated from a source, the field interacting with one or more structures, the system being configured to: provide a simulation space comprising a domain that contains the source and the one or more structures; simulate the field within the domain based at least in part on an operator acting on the field; divide the domain into a plurality of subdomains; designate a first iteration of the field; determine a residual source based on the operator acting on the first iteration of the field throughout the domain; iteratively solve for the field by solving for residual field behavior in a subset of the subdomains; wherein solving for residual field behavior in a subdomain of the subset comprises: the operator acting on the residual field within an extended subdomain around the subdomain; and where the subdomain comprises a structure, extending a boundary of the structure located at a boundary of the extended subdomain, beyond the boundary of the extended subdomain to a second extended subdomain.

In some embodiments, the operator may be modified to include a loss; and simulation may further comprise one or more convergence cycles in which the modified operator acts on a modified residual field.

In addition, simulation may further comprise using a Green's Function method to solve for the local residual field when the subdomain is filled with uniform space; using a slab-iteration method to solve for the local residual field when the subdomain has a one-dimensional asymmetry; and using either a steady-state method with absorbing boundary conditions or a time-stop method, to solve for the local residual field when the subdomain is neither filled with uniform space nor has the one-dimensional asymmetry. In some embodiments, simulation may further comprise applying the time-stop method when the subdomain is a border subdomain and applying the steady-state method with absorbing boundary conditions when the subdomain is an interior subdomain.

In some embodiments, the field can be an electromagnetic field, a fluid flow field, a heat conduction field, a diffusion field or an electrostatic field. In an embodiment, the field is an electromagnetic field that satisfies a modified form of Maxwell's equation:

$$( \begin{matrix}- i ωɛ + σ & {∇}^{⟶} \times \\ - {∇}^{⟶} \times & - i ωμ + {σ}_{h}\end{matrix} ) ( \begin{matrix}{E}^{⟶} \\ {H}^{⟶}\end{matrix} ) = ( \begin{matrix}{{J}^{⟶}}_{s} \\ {{J}^{⟶}}_{hs}\end{matrix} )$$

and the one or more structures can comprise at least one waveguide or at least one transmission line. Here \vec{J}s and \vec{J}hs denote source currents which serve to provide a source of field for the simulation. These may be used to generate, for instance, an incident waveguide mode on one interface.

In some embodiments, the simulation can further comprises the steps of: a) determining a new source based on operation of the operator on a current iteration of the field; b) determining the global residual source based on a difference between the new source and the source; c) ending simulation and setting the field equal to the current iteration of the field, if a magnitude of the global residual source is less than a first pre-set threshold; d) if the magnitude of the global residual source is greater than the first pre-set threshold, scanning the plurality of subdomains to determine the subset of subdomains, each subdomain within the subset having a local residual source magnitude greater than a second pre-set threshold; e) constructing the extended subdomain around the subdomain; f) solving for a local residual field within the extended subdomain; g) adding all of the local residual fields from the subset to provide a new estimate of the field; h) setting the current iteration of the field equal to the new estimate of the field; and i) repeating steps (a) through (h) until the magnitude of the residual source is less than the first pre-set threshold.

Additional aspects, advantages, and embodiments of the method will become apparent to those skilled in the art from the following description of the embodiments, the drawings and the claims.

Embodiments are described below with references to the accompanying drawings in which like elements are referenced with like reference numerals.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a problem of interest that is solved in accordance with one embodiment.

FIG. 2 illustrates a flowchart in accordance with one embodiment.

FIG. 3 illustrates a Table 300 in accordance with one embodiment.

FIG. 4 illustrates a first phase of a void-space domain decomposition (VSDD) method in one embodiment

FIG. 5 illustrates an equivalent VSDD problem in accordance with one embodiment.

FIG. 6 illustrates a flowchart for solving for a subdomain residual field in accordance with one embodiment.

FIG. 7 illustrates a time-stop method in accordance with one embodiment.

FIG. 8 illustrates a Green's Function method in accordance with one embodiment.

FIG. 9 illustrates a slab-iteration method in accordance with an embodiment.

FIG. 10 illustrates a slab-iteration method in accordance with another embodiment.

FIG. 11 illustrates adaptive meshing in accordance with one embodiment.

FIG. 12 illustrates subdomain amalgamation in accordance with one embodiment.

FIG. 13 illustrates use of multiple solution methods in accordance with one embodiment.

FIG. 14 illustrates a block diagram of an embodiment of a system for implementing the VSDD method on a computer.

FIG. 15 illustrates a simulation of an electromagnetic field in the presence of two waveguides.

FIG. 16 illustrates the simulation of the configuration shown in FIG. 15 after 20 minutes of run-time.

### DETAILED DESCRIPTION

The subject matter is described, however, the description itself is not intended to limit the scope of the method. The subject matter thus, might also be embodied in other ways, to include different steps or combinations of steps similar to the ones described herein, in conjunction with other technologies. Moreover, although the term “step” may be used herein to describe different elements of methods employed, the term should not be interpreted as implying any particular order among or between various steps herein disclosed unless otherwise expressly limited by the description to a particular order.

The Void Space Domain Decomposition (hereafter referred to as “VSDD”) method divides up a domain of interest (in two dimensions or three dimensions) for the purpose of finding a solution for a model problem or simulation in science or engineering.

The VSDD method can be applied to a number of different equations that describe physical processes, even though the variables and the equations involved have different forms. For example, the solution of Maxwell's equations (in electrodynamics), either in the optical or RF regime, requires the solution of an equation in 6 variables—namely the three components of the electric field (Eₓ, E_{y}, E_{z}) and the three components of the magnetic field (Hₓ, H_{y}, H_{z}), with an operator that includes two curl operations. The solution of equations of electrostatics, however, requires the solution of a single scalar potential, with the application of Laplacian. In some material systems, such as anisotropic systems, these equations may take slightly different forms. However, the VSDD method does not depend on the particular form of the equation that describes a physical process of interest; the method relies on the principle that the solution for the system as a whole can be obtained by iterating through a solution of a “void space equivalent problem” for each subdomain in the manner described herein.

A steady-state solution or a static solution can be obtained by iteratively applying the VSDD method to a series of subdomains. In contrast to the prior art, described herein are several techniques for obtaining solutions in the subdomains that are located on the border of the global domain, in a manner that can contribute far less unrecoverable error to the solution obtained in the model or the simulation. Therefore, upon convergence of the iterative procedure used in the VSDD method, a final solution is far more accurate than conventional domain-decomposition approaches. The solution obtained by the VSDD method also has greater applicability in many situations. Moreover, several techniques described herein, significantly speed up the simulation process.

Overall, the VSDD method provides a practical method for obtaining an exact discrete solution of many used in science and engineering to describe physical processes. In addition, the VSDD method can be scaled in a favorable manner for distributed computation. The VSDD method scales in a superior manner when compared to solving the equivalent large linear system or performing even an explicit iterative method such as FDTD. Hence, the VSDD method provides an advantageous approach to obtaining exact discrete solutions to equations of scientific and engineering models.

The VSDD method can be used with either finite-element or finite-difference approaches. The VSDD method is most useful for either finite-difference, or finite-element with a structured mesh. It should be noted that a number of the solution techniques described for the VSDD method herein work with mesh points that occur at uniform intervals. That is, a generalized finite-element mesh cannot be used in such specific cases, unless it is structured to have uniform point spacing.

Even if finite element is in use, so long as the points form a lattice with uniform spacing in each dimension, one can always use approaches such as the Green's Function method or slab iteration method—both of which are described below. The lattice has a discrete translational symmetry.

In summary, application of the VSDD method to border subdomains minimizes unrecoverable error. While interior subdomains do not require the VSDD method to avoid unrecoverable error, they may still require the VSDD method for the iteration as a whole to converge. Solving the VSDD equivalent problem thus provides at least two advantages: to minimize error on the boundaries of the global domain, and to enable or speed up convergence for the problem as a whole.

Partial differential equations that describe a variety of physical phenomena, have a general form:

Âχ=β Eq. 1

where Â is a partial differential operator, χ is a field, and β is a source. As an example, in the field of electrodynamics, a modified form of Maxwell's equations that describes electric (E) and magnetic (H) fields, is written as follows:

$$( \begin{matrix}- i ωɛ + σ & {∇}^{⟶} \times \\ - {∇}^{⟶} \times & - i ωμ + {σ}_{h}\end{matrix} ) ( \begin{matrix}{E}^{⟶} \\ {H}^{⟶}\end{matrix} ) = ( \begin{matrix}{{J}^{⟶}}_{s} \\ {{J}^{⟶}}_{hs}\end{matrix} ) \qquad Eq . 2$$

In this example,

$$\begin{matrix}{A}^{⟶} = ( \begin{matrix}- i ωɛ + σ & {∇}^{⟶} \times \\ - {∇}^{⟶} \times & - i ωμ + {σ}_{h}\end{matrix} ) & Eq . 2 a \\ X = ( \begin{matrix}{E}^{⟶} \\ {H}^{⟶}\end{matrix} ) & Eq . 2 b \\ β = ( \begin{matrix}{{J}^{⟶}}_{s} \\ {{J}^{⟶}}_{hs}\end{matrix} ) & Eq . 2 c\end{matrix}$$

where \vec{E} includes 3 components of the electric field vector; \vec{H} includes 3 components of the magnetic field vector; \vec{J}s includes the three components of the source electric current, and \vec{J}hs includes three components of the source magnetic current. It should be noted that while entities Ĵhs (magnetic “current”) and σₕ (magnetic “conductivity”) are used frequently in the art as part of the modified Maxwell's equation, it is understood that neither are physical entities. The source current refers to a term that is analogous in units to the actual physical current (σ\vec{E} in the case of \vec{J}s for instance), but which has been selected to generate a set of fields for the problem of interest, as mentioned above. For example, one could select a β value that would launch a particular input mode at a waveguide interface.

While the field χ and source β are each a vector in Eq. 2, each may be a scalar in other physics equations. For example, in steady-state heat conduction, the field χ is the temperature (a scalar), while the source β is a heat source (also a scalar).

When a simulation is performed to solve for Eq. 1, the operator Â, field χ, and source β are discretized, such that Eq. 1 takes the form:

[symbol]

·\vec{X}=\vec{B} Eq. 3

where:
[symbol] =operator
\vec{X}=solution vector
\vec{B}=source vector,

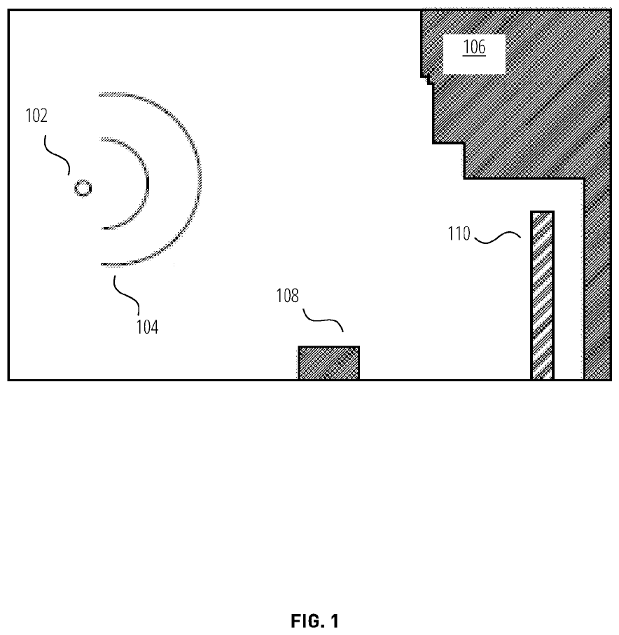

In FIG. 1, 100 represents a problem of interest whose solution is sought. Source 102 provides a stimulus. For example, in electrodynamics, source 102 is a source current. Source field 104 indicates propagation of, for example, a field, elastic displacement, or other phenomenon as a result of the disturbance. In FIG. 1, three structures are shown: structure 106, structure 108 and structure 110.

The general Eq. 1 is converted to a discretized form as shown in Eq. 3. What is sought is the solution to Eq. 3, with the various structures representing boundary conditions.

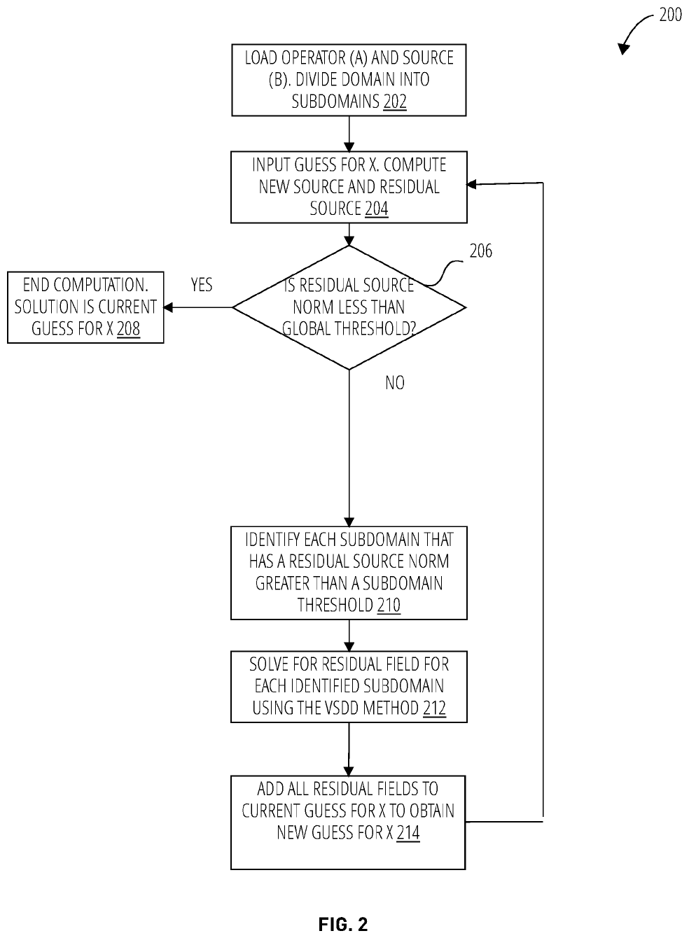

FIG. 2 illustrates a flowchart 200 used to obtain the solution to the problem illustrated in FIG. 1, in accordance with one embodiment.

In step 202, the operator A and source B are loaded into the simulation program. The problem domain is divided into a series of subdomains.

At step 204, an initial guess for \vec{X}=\vec{X}₁ is input, which leads to a new source B₁:

[symbol]

·\vec{X}₁=\vec{B}₁ Eq. 4

As an example, the initial guess may be \vec{X}₁=\vec{0}. At this stage, the outermost layer of grid points at the very boundary of the entire simulation domain may be zeroed for \vec{B}₁. Furthermore, a discretized linear version of the operator [symbol] is defined.

A residual source, δ\vec{B}₁, may be defined as the difference between the new source \vec{B}₁ and the original source \vec{B}:

δ\vec{B}₁=\vec{B}−\vec{B}₁ Eq. 5

At step 206, the norm (or magnitude) of the residual source, N₁, is computed, and compared to a global threshold:

N₁=|\vec{B}·\vec{B}₁|<Global threshold? Eq. 6

If the answer is yes, then the current guess (or iteration) of \vec{X} has converged and a sufficiently accurate solution has been found; the computation stops at step 208. The solution may be recorded, displayed, or provided to another process for later use, and the iterative process ends.

If the answer is ‘no’ at step 206, then each subdomain is scanned to identify which of the subdomains has a local residual source magnitude, N₁, that is greater than a subdomain threshold at step 210. These identified subdomains are then solved for.

For each subdomain that is identified in step 210, the VSDD method is used to solve for a residual field \vec{Y}₁, at step 212, that gives rise to the local residual source δ\vec{B}₁:

[symbol]

·\vec{Y}₁=δ\vec{B}₁ Eq. 7

At step 214, the next iteration of \vec{X} is obtained by adding all of the residual fields (that were obtained in step 212) to the current iteration of \vec{X}. As is described in detail below, while the residual field \vec{Y}₁ extends throughout the entire problem domain, only that portion of \vec{Y}₁ that extends slightly beyond the subdomain, is used to update the iteration of \vec{X}.

For example, if a total of ‘m’ subdomains were identified in step 210, then the next iteration of the solution \vec{X}₂ is:

\vec{X}₂=\vec{X}₁+\vec{Y}₁⁽¹⁾+\vec{Y}₁⁽²⁾+ . . . +\vec{Y}₁^{(m)} Eq. 8

The superscript (i) on \vec{Y}⁽ⁱ⁾ denotes the residual field in domain ‘i’, while the subscript ‘1’ of \vec{Y}₁ indicates the iteration number. The new iteration, \vec{X}₂, is then input back at step 204 and a new residual source is computed:

[symbol]

·\vec{X}₂=\vec{B}₂ Eq. 9a

δ\vec{B}₂=\vec{B}−\vec{B}₂ Eq. 9b

At step 206, the norm of the residual source is computed and compared to the global threshold:

N₂=|\vec{B}−\vec{B}₂|<Global threshold? Eq. 10

If this condition is satisfied, then the computation ends at step 208; the iterated solution \vec{X}₂ is within the threshold; if not, all of the subdomains are once again scanned to identify those subdomains that have a local residual source that exceeds the subdomain threshold at step 210; steps 212-214 are repeated, and a new iteration for \vec{X} is obtained and input at step 204. This loop is repeated until the norm of an iteration of the residual source is less than the global threshold, and the computation ends at step 208.

The number of iterations per subdomain that are performed before global convergence is reached may be any number. In some embodiments, the number of iterations may be from 2 to 200, or from 5 to 150, or from 10 to 101. In some embodiments, far fewer, or even no iterations maybe needed for some subdomains, if there is minimal nonzero residual source in such subdomains throughout the solve process. However, the number of iterations per subdomain may increase in the case of some high Q resonances, and in some embodiments, the number of iterations may decrease. Note that in other approaches, methods such as FDTD require vastly increased computational times, and iterative matrix methods that attempt to solve the entire problem—without any subdomain decomposition—require increased computational time as well.

Many variations of the flowchart 200 are possible. For example, in different embodiments, the subdomain threshold value may change as the simulation progresses. It is also possible to have the subdomain solve processes on each subdomain proceed independently, whereby the vector \vec{X} is continually scanned, the new residual source δ\vec{B} calculated, and the corresponding subdomain (or subdomains) solved whenever the value is above a pre-set threshold. The pre-set threshold can be understood as a value of an error that is considered to be an acceptably small error value. Once the computation provides an error smaller than the predetermined threshold, the iterated solution vector \vec{X}₁ is considered acceptable, and the computation is terminated.

Another technique that can be used is to artificially add a small loss term to the discretized operator A, resulting in a modified operator A_{M}. As an example, in the case of electrodynamics, this loss can amount to adding a slight artificial conductivity to the materials in the simulation, resulting in an absorption of electromagnetic radiation. By using the modified operator A_{M}, the solution can converge more rapidly, although a slight inaccuracy may be introduced (although it is often a small percentage change in the final solution value of interest). Then, by repeating this iteration and adding a correction for the loss term periodically, convergence to the exact solution with no inherent error due to this added loss term may be achieved.

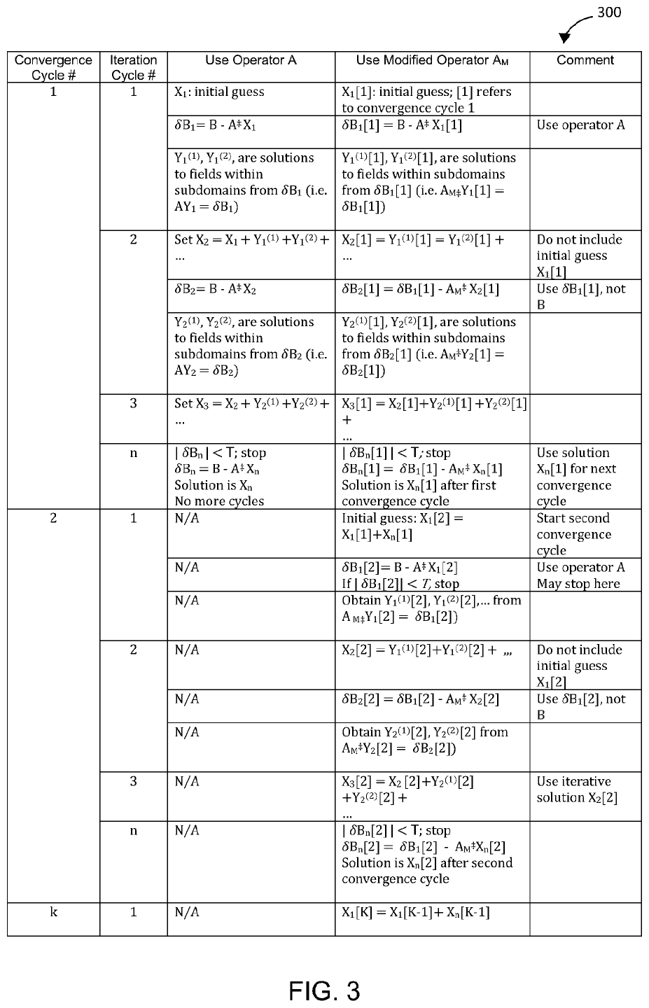

Table 300 in FIG. 3 provides an example of using the modified operator A_{M} over a number of convergence cycles (with the bracket [N] representing the ‘Nth’ convergence cycle), to arrive at a solution. This is in contrast to using the original discretized operator A, in which only one convergence cycle is performed. As shown in the column (labeled ‘Use Operator A’), the discretized operator A is used over the course of the one cycle, during which convergence happens after ‘n’ iterations, and the solution Xₙ is obtained.

For example, regardless of the convergence cycle, the original discretized operator A is only used during the first iteration to find the residual source δB₁[N]:

δB₁[N]=B−A*X₁[N] Eq. 11

During the first iteration, the residual fields Yᵢ[N] are solutions to application of the modified operator A_{M}. For example, during the first convergence cycle:

A_{M}*Y₁[1]=δB₁[1] Eq. 12

In the second iteration, the next guess X₂[1] is the sum of the residual fields, and does not include the initial guess X₁[1]:

X₂[1]=Y₁⁽¹⁾+Y₁⁽²⁾[1]+ Eq. 13

However, at the third iteration, the previous solution is used:

X₃[1]=X₂[1]+Y₂⁽¹⁾[1]+Y₂⁽²⁾[1]+ Eq. 14

The iteration is continued until the residual source norm is less than a pre-set threshold ‘T’. However, the process does not end here. A second convergence cycle is initiated, where the initial guess includes the initial guess at the first convergence cycle (X₁[1]) and the solution at the end of the first convergence cycle (Xₙ[1]):

X₁[2]=X₁[1]+Xₙ[1] Eq. 14

At this stage, the norm of δB₁[2] is evaluated; if it is less than the threshold ‘T’, then no further iteration is made during the second convergence cycle; the solution is given by Eq. 14. If the norm is greater than threshold ‘T’, the iteration proceeds until convergence within the second convergence cycle is obtained. The process is repeated until the norm of the first iteration of the residual source is less than the threshold ‘T’. In practice, the number of convergence cycles is about 2 or 3; in some cases, only one convergence cycle may be needed. That is, in some embodiments, (as shown in Table 300) K≤3.

The VSDD method is highly advantageous with regard to scaling across multiple computers for cloud computation. Extensive data may only need to be exchanged between computational nodes once—at the start and end of each subdomain solution process. This is in contrast to FDTD and other methods that involve solving a single large matrix equation, where a great deal of data must propagate between the nodes for every time step (FDTD) or, usually, every iteration involving the solution of the matrix equation for the complete system. There are usually at least thousands, perhaps tens of thousands, or more iterations associated with FDTD or other methods that involve solving a large matrix equation. In addition, the subdomain solve step 212 can proceed on multiple computational nodes in parallel. Hence the VSDD method is uniquely suited to scaling for embodiments that can operate on a large number of parallel computers. That is, parallel processing used in conjunction with the VSDD method speeds up simulation run times.

The next sections describe the domain decomposition into subdomains and embodiments of the VSDD method.

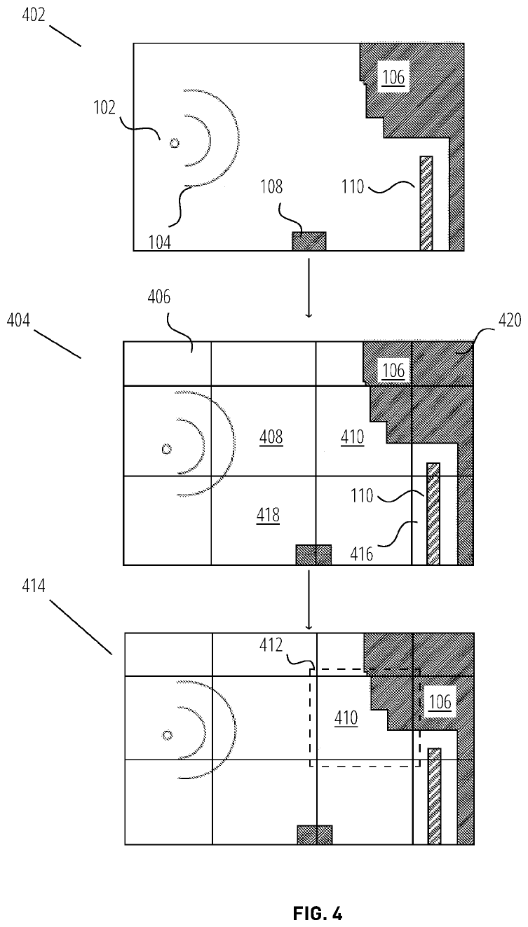

FIG. 4 illustrates a first phase of a void-space domain decomposition (VSDD) method in an embodiment. At this stage, the residual source has a magnitude that exceeds the global threshold at step 206 of FIG. 2. As an example, the VSDD is applied to the scenario shown in FIG. 1.

A first step in the VSDD method is to select a problem domain, which may be in two dimensions or three dimensions, and divide the problem domain into a series of subdomains.

In FIG. 4, 402 illustrates the scenario shown in FIG. 1, while 404 illustrates the decomposition of the problem domain illustrated in FIG. 1 into subdomains that are used in the VSDD method. This can be a two-dimensional (2D) simulation or a 2D-sectional view of a three-dimensional (3D) simulation. These subdomains are created as part of the VSDD domain decomposition process. The VSDD method can also be applied to one-dimensional problems.

Almost all scenarios have some form of nonuniformity within the problem. For example, in an embodiment involving electrodynamics, the nonuniformity may be a dielectric region which impedes optical flow. In an embodiment involving structural mechanics, the nonuniformity may be a region with a varying elastic constant. Regardless of the exact features of the various structures (or nonuniformity), the problem can be solved iteratively, in that each subdomain may be solved for a local residual stimulus within the subdomain. The resulting residual field is obtained via the VSDD method, and extends into neighboring subdomains; this residual field is converted into a new stimulus (or source) for neighboring subdomains, and the process continues iteratively through a new cycle of calculations as outlined in FIG. 2.

For the sake of clarity, only a few subdomains are labeled in FIG. 4: subdomain 410, subdomain 406, subdomain 408, subdomain 416, subdomain 418 and subdomain 420. Note that subdomain 410 encloses a portion of the structure 106, while subdomain 416 encloses parts of structure 106 and structure 110; subdomain 418 encloses a portion of structure 108. On the other hand, subdomain 406 and subdomain 408 are empty, in that neither encloses any structure. Furthermore, subdomain 406, subdomain 416, subdomain 418 and subdomain 420 are each designated as a border subdomain, while subdomain 408 and subdomain 410 are each designated as an interior subdomain.

At this stage, the VSDD method is only applied to those subdomains in which the residual source has a magnitude greater than a pre-set subdomain threshold. In FIG. 4, 414 illustrates further manipulation of the subdomains for use in an embodiment of the method. As an example, suppose subdomain 410 has been identified as having a magnitude of the local residual source greater than the subdomain threshold. Subdomain 410 is surrounded by an extended subdomain 412 (indicated by the dashed box) that is used in an iterative method as part of the VSDD method.

The division (of the full domain) into subdomains has minimal or no influence on the final solution vector once convergence is obtained—which occurs when the VSDD method is applied for a sufficient number of iterations. In other words, when final convergence is obtained, one can expect a smoothly varying solution that shows no evidence of the location of the subdomains.

The use of subdomains may provide distinct computational advantages over conventional single domain approaches. For example, if a 3D uniform domain of 3000×3000×3000 grid points is used, and floating point precision is used, approximately 0.6 Terabytes is required to store a single copy of the solution vector alone. Solving a steady state equation involving a matrix equation of this size is impractical. Such a domain is also beyond the capability of FDTD, finite-element or other conventional methods in most cases.

Instead, if this domain is divided into 50×50×50 subdomains (resulting in approximately 125,000 subdomains), the solution process can be distributed to about 100 computer nodes; if 10 iterations per subdomain are required for convergence, and 5 seconds per subdomain solution, the simulation time for this large domain is only about a day. In some embodiments, more than a hundred computers can be efficiently used, thereby further lowering the time required to solve the problem.

In an embodiment of the VSDD method, the subdomains can be solved using what is termed as the “void space equivalent” problem. That is, instead of solving the exact problem within the individual subdomain 306, an equivalent problem is solved, and the solution thereof is used to formulate a new iteration. This differs from prior art methods and provides solution convergence; when applied on a border subdomain, the VSDD method vastly reduces unrecoverable error.

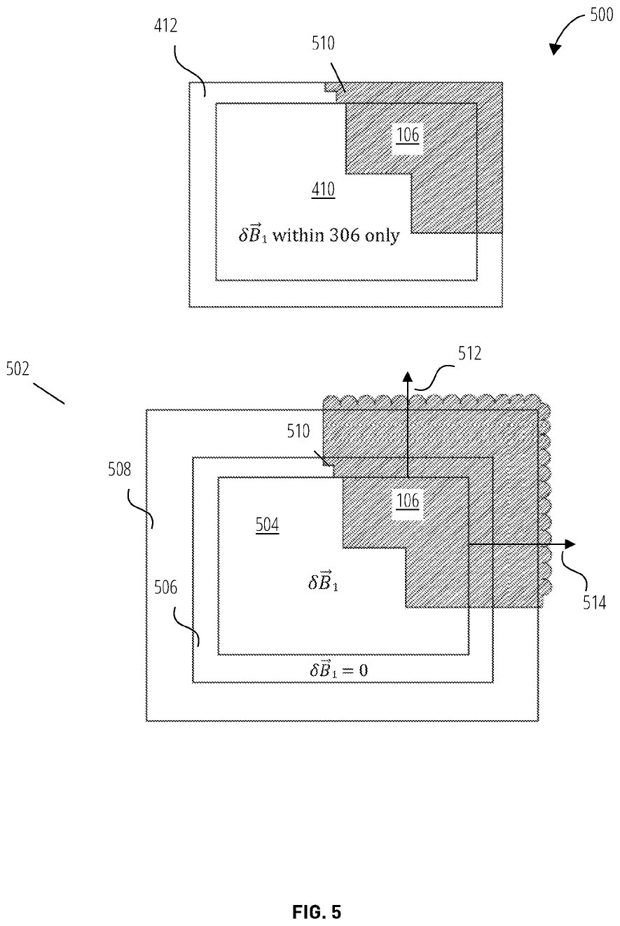

The void space equivalent problem involves taking a subdomain and the residual stimulus within this subdomain and extending the solution slightly beyond the bounds of the subdomain. If a subdomain includes a structure (or part of a structure), there is an additional condition in which the structures are extended (artificially) in order to solve for the residual field. This approach is illustrated in FIG. 5.

FIG. 5 illustrates a setup 500 of an equivalent VSDD problem 502 for subdomain 410 shown in FIG. 4. FIG. 5 can be interpreted as either a diagram in 2d or a cross-section of a 3d domain set. Extended subdomain 412 includes structure portion 510 that forms part of structure 106, but is not within subdomain 410. In an embodiment involving electrodynamics, structure 106 can comprise, or be represented by, a dielectric region or a region with enhanced conductivity as compared to background material.

In the equivalent VSDD problem 502, subdomain 504 is equivalent to subdomain 410 in the original problem, while extended subdomain 506 is equivalent to extended subdomain 412 in the original problem. For example, extended subdomain 506 also includes the structure portion 510 of structure 106. Extended subdomain 506 (and thus extended subdomain 412) may enclose subdomain 504 by at least one pixel layer (or voxel layer in 3-dimensions). A voxel is unit cube with a dimension of 1 pixel×1 pixel×1 pixel. A pixel layer is defined as a single row of finite difference or finite element points, while a voxel layer is defined as a three-dimensional rectangle of finite difference or finite element points.

The residual source within subdomain 504 is solved to produce a field pattern within extended subdomain 506. As part of the VSDD iteration, an additional extended subdomain 508 is created. Within extended subdomain 508, structure 106 is extended out uniformly as shown with arrows 512 and 514. To solve the void space equivalent problem exactly, extended subdomain 508 would be expanded out endlessly. Due to limited computational resources, this is not possible. Instead, absorbing boundary conditions (referred to as “ABCs”) can be added on extended subdomain 508. Examples of such conditions include a perfectly matched layer (PML) or Mur boundary conditions in the case of electrodynamics. Or the time-stop method (described below) can be used, which results in a solution that closely matches that obtained if the boundary of extended subdomain 508 were extended to infinity. Often, the time stop method may provide a better approximation to the void space equivalent problem. However, using ABCs with a sufficiently long extension of extended subdomain 508 (away from extended subdomain 506) can approximate the exact VSDD solution.

In the equivalent VSDD problem 502, the edges of the structure 106, at the outer boundary of extended subdomain 506, are extended infinitely normally outwards (as indicated by arrows 512 and 514). Practically, though, the boundary of the extended subdomain 508 may be set as a “cutoff” boundary.

The equations for the equivalent VSDD problem 502 are thus:

[symbol]

·\vec{Y}₁=\vec{C} within the VSDD “boundary” defined by 410,

where \vec{C}=δ\vec{B}₁ within 406,

and \vec{C}=\vec{0} outside of 406. Eq. 11

The solution \vec{Y}₁ is retained within all of extended subdomain 506, and may be truncated at the outer boundary of extended subdomain 506. Details on how to obtain the solution \vec{Y}₁ are discussed below.

Returning to FIG. 4, in the domain decomposition diagram 414, the solution \vec{Y}₁ is superimposed on all of extended subdomain 412 (note that \vec{Y}₁ only exists within extended subdomain 412, and is equal to zero outside of extended subdomain 412). This solution \vec{Y}₁ is added to the current iteration (or guess) \vec{X}₁. It should be noted that within the original subdomain 410:

[symbol]

·(\vec{X}₁+\vec{Y}₁)=\vec{B}₁+\vec{C}=\vec{B}₁+δ\vec{B}₁=\vec{B} Eq. 12

That is, \vec{X}₁+\vec{Y}₁ is the solution to Eq. 1 within subdomain 410 (provided no neighboring subdomains are solved).

If subdomain 410 is the only subdomain in which the VSDD equivalent problem is solved (i.e. there are no other subdomains to process), then the next iteration is simply:

\vec{X}₂=\vec{X}₁+\vec{Y}₁ Eq. 13

The new iteration is input at step 204 in FIG. 2, and the remaining steps are repeated until step 208 is obtained.

One may elect to scale the addition by a real scale factor ‘α’ that may be on the order of 1 or somewhat lower (for example α=0.2 to 1.5, or α=0.4 to 1, or α=0.7):

\vec{X}₂=\vec{X}₁+α\vec{Y}₁ Eq. 14

Also, in some embodiments the edges of the solution vector may be “smoothed” by a spatial function such as a Gaussian. Both of these techniques (i.e. scaling and smoothing) can help convergence in some cases, especially where there is any kind of resonance or internal reflection.

On the other hand, if subdomain 410 is not the only subdomain to be processed, then the equivalent VSDD problem is solved for within each identified subdomain; the solution \vec{Y}₁^{(k)} of the “k^{th}” subdomain is solved, the new iteration is as defined in Eq. 8 for all the ‘m’ identified subdomains in the first iteration:

\vec{X}₂=\vec{X}₁+\vec{Y}₁⁽¹⁾+\vec{Y}₁⁽²⁾+ . . . +\vec{Y}₁^{(m)} Eq. 8

Note that the processing of all of the identified subdomains are independent of each other, and can proceed in parallel—for example, on separate computers. This provides a key advantage of the VSDD method compared to approaches that do not use domain decomposition.

The equivalent VSDD problem 502 may be solved, depending on the characteristics of the structure within the subdomain 504, as described below.

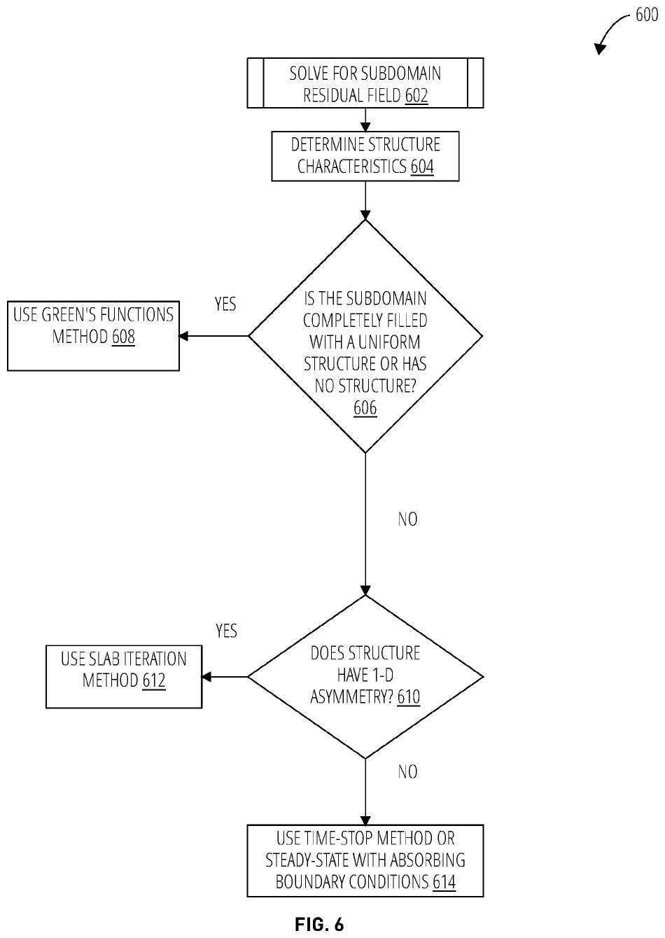

FIG. 6 illustrates a flowchart for solving for a subdomain residual field in accordance with one embodiment.

At step 604, the characteristics of any structure within the subdomain are determined. A series of evaluations are made. At step 606, if the subdomain is completely filled with a uniform structure, then the Green's Function method is used to solve for the subdomain residual field in the equivalent VSDD problem (in step 608). This also applies if the subdomain has no structure within, since the space within the subdomain is uniform.

On the other hand, if the structure within the subdomain has a one-dimensional asymmetry (step 610), then a slab iteration method can be used to solve for the subdomain residual field in the equivalent VSDD problem (in step 612).

Finally, if the subdomain has a non-uniform structure, without 1-D asymmetry, a time-stop method or steady-state with ABCs can be used to solve for the subdomain residual field in the equivalent VSDD problem (step 614).

Each of the following procedures: steady-state with ABCs, time-stop, slab iteration and Green's functions, are briefly described below.

In a variation of FIG. 6, it is still possible to use the steady-state method or the time-stop method in cases where the subdomain is uniform throughout or has a one-dimensional asymmetry. However, use of the Green's Function and slab iteration methods have lower computational costs.

To approximately solve the problem shown in FIG. 5, one may use a steady-state solution with absorbing boundary conditions (ABCs). This method may be used since subdomain 410 contains a portion of structure 106; as such subdomain 410 satisfies condition 614 in FIG. 6. In many embodiments the ABC location can be chosen at the outer boundary of extended subdomain 508, outside the extended subdomain 506 in which the residual field is to be captured. If extended subdomain 508 is far beyond extended subdomain 506, use of ABC may lead to a much better approximation of the VSDD problem—however, it may be more computationally expensive.

Use of an ABC-based method to solve for “border” subdomains (e.g. subdomain 406 or subdomain 416 in FIG. 4) may introduce unrecoverable errors in the simulation. For “border” subdomains, the equivalent VSDD problem can be solved using the time stop technique, which is describe following this section. As discussed below, although the time-stop technique contributes some error, nonetheless the error is greatly reduced (compared to that introduced by the ABC).

Since subdomain 410 is an “interior” subdomain, the equivalent VSDD problem 502 is suited for the ABC-method. In an embodiment, a simple set of ABCs can be applied which simulate endless space, and solve the void space equivalent problem only approximately. Performing a solution on a small subregion with ABCs is a tractable problem. For example, iterative matrix solvers can be successfully used. The VSDD method continuously compares the solution at a given time to the underlying linear operator and minimizes this residual over time. Hence, any intermediate solution for the interior subdomains can be added to the most recent overall solution without generating any unrecoverable error. So long as the global iteration converges, one does not need to solve the perfect void space equivalent problem internally.

For border subdomains, a better approximation is usually used to solve the void space equivalent problem. One such method is the time-stop method, which is described below. It should be noted a number of methods can be used to solve within a border subdomain, with the method of choice depending on the structure within the subdomain. Regardless of the method chosen, the eventual residual source pixel layer (or voxel layer in 3 dimensions) at the outermost edge of the subdomain is discarded during the course of calculation. While this may introduce a minimal amount of error, the introduced error is not as large as in conventional approaches.

The Time Stop Method

The “time stop” subdomain solution method is a component of the VSDD iteration method. In situations where a border subdomain has a nonuniform structure configuration, the Green's function method or slab iteration method cannot be used. Moreover, applying an ABC (which is what is done in the IMR method), does not approximate the void space equivalent problem closely enough, although by greatly expanding the distance from extended subdomain 506 to extended subdomain 508 it may be possible to improve accuracy. The time stop subdomain solution method uses time as a filter by which to mimic the behavior of the void space equivalent problem.

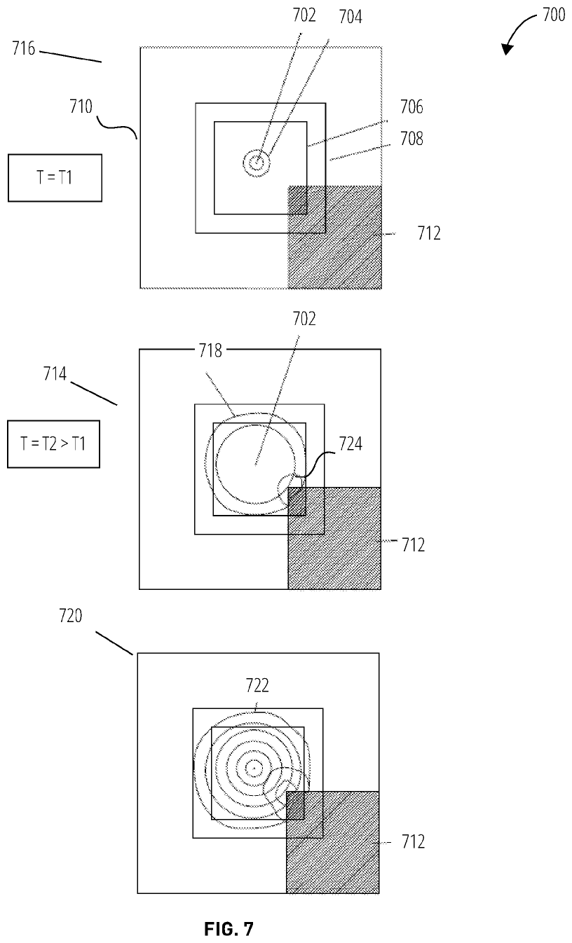

FIG. 7 is a schematic diagram 700 that illustrates an embodiment in which the “time stop” method may be used to solve the void space equivalent problem for a border subdomain that has a nonuniform structure. Therefore, neither the Green's function method nor slab iteration method can be used on such a subdomain. A series of “time stops” is shown in successive diagrams 716 and 714.

In diagram 716, at an initial time T=T1, source 702 launches an excitation 704 (due to a source) into the original subdomain 706. The stimulus to be applied in the time stop method is fully contained within subdomain 706. The excitation 704 may in various embodiments be an electromagnetic wave, an acoustic wave, a thermal pulse, or any other perturbation or excitation of interest. By way of example, source 702 may be a point radiation source in an electrodynamics simulation. Enclosing the original subdomain 706 is the extended subdomain 708 which encloses the region from which a solution vector is to be obtained.

Finally, at a significant distance the border 710 indicates the outermost limits of the time domain simulation, which will also contain an ABC. A structural element 712 is present, which is extended to the outermost border 710 in the void space equivalent manner described previously.

A short time after, at T=T2, diagram 714 illustrates an evolution of the “time stop” method relative to 716. In 714, the excitation 704 has traveled away from source 702. At different points in time, based on distance and possibly the relevant physical properties of the content of a region in a subdomain, the excitation 704 “flows” through the subdomain 706 and impinges on the various structures or reaches a boundary of a subdomain. In 714, the flowing excitation is denoted by 718. Note that at T=T2, the original excitation 704 has reached structural element 712, and produced a reflection 724.

Panels 716 and 714 illustrate the principles of the time stop method. First, one takes the equivalent time domain problem associated with the steady state or static partial differential equation that are being solved. For Maxwell's equations, this would simply be the time-domain Maxwell's equations. For a static problem such as electrostatics, the approach involves the introduction of a dispersive equation modeling the propagation of a voltage (represented by an electromagnetic wave) in a manner similar to a time-dependent diffusion problem. Then one uses as the subdomain an extension of the original subdomain into a void space equivalent problem—in this case, explicitly extending the solution domain considered. ABCs may be added, but these will be of limited utility as they are not expected to perfectly absorb the outgoing radiation even if spaced far back from the original subdomain. In any case, the progress of the solution will involve a wave-front of sorts propagating out from the source 702, which is located only in the original subdomain 706. The wave-front will eventually reach the border 710, and begin to reflect back, even if there are ABCs. In the meantime, for a steady-state type solution, one may perform Fourier filtering to extract the solution pattern in the frequency domain from the time domain solution within the original subdomain, and possibly a small region extending around it. For a static type solution one can simply observe the solution vector at the end of the simulation runtime. The time domain simulation can then be terminated for this extended subdomain before the disturbance from the extended subdomain boundary reaches the region in which the solution vector is being derived. Then, the solution vector captured from this method, even if it does not exactly solve for the given stimulus, is equivalent to the exact void space solution.

This insight, on its own, is not enough to solve the void space equivalent problem. The issue is that the solution vector so captured will almost certainly not be a solution for the given stimulus. To complete the time stop method, one must then take the new residual current, and re-run the time domain simulation again, once again terminating the iteration before the reflection from the extended subregion border has disturbed the region of solution vector capture. This process must be repeated and at each point, one can take a vector space of all subdomain solution vectors computed and find the best fit subdomain solution that minimizes the residual with the stimulus at a given time. A linear combination of solution vectors that individually satisfy the void space equivalent problem boundary conditions will also, when added together, satisfy the same condition. Repeating this process eventually leads to the exact void space equivalent problem solution. In practice, few iterations are needed; for example, less than 15, or between 2-15, or usually about 3-4.

720 shows a resulting steady state solution vector pattern that can be captured as a result of the time domain simulation. The captured steady-state pattern 722 is shown. In an embodiment, such as in the case of electrodynamics, one might use FDTD and the steady state field pattern would be captured using Fourier filtering. With the FDTD, since a few of the wave fronts may remain inside the subdomain when the time evolution was halted, and also due to intrinsic error in Fourier filtering, the solution thus captured by the FDTD will not exactly satisfy the invariant underlying linearized differential equation within this subdomain. However, as described previously, the solution will satisfy the void space boundary conditions provided the time evolution is halted at the proper time, before any reflections from the ABC at border 710 can occur. Hence, this iteration can be performed multiple times, and eventually combine the results and use a best fit method to obtain an excellent approximation to the true void space equivalent problem for this subdomain.

Green's Function Method

Green's functions are used in physics, in embodiments involving quantum field theory, aerodynamics, aeroacoustics, electrodynamics, seismology and statistical field theory—and often refer to various types of correlation functions, even those that do not fit the mathematical definition. For example, in quantum field theory, Green's functions serve as propagators.

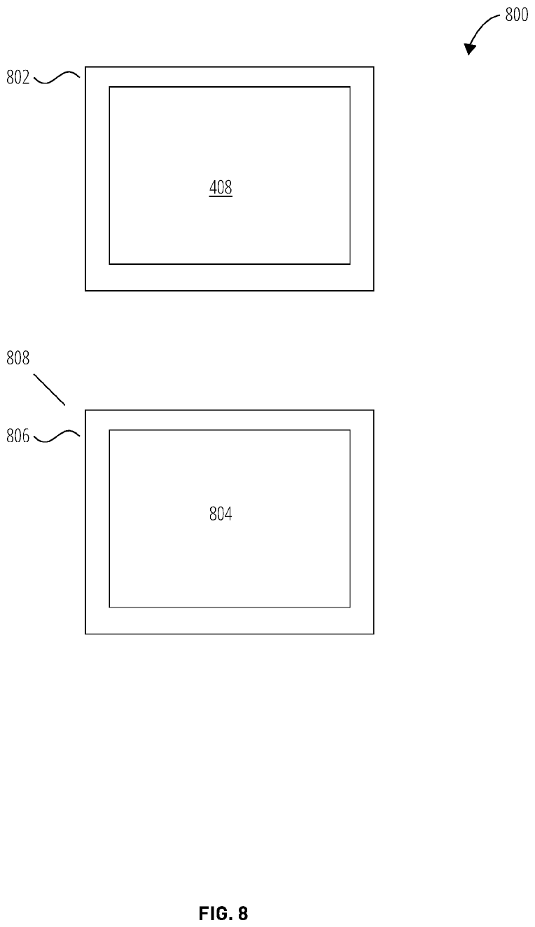

FIG. 8 illustrates an embodiment of the method in which solution of the void-space equivalent problem is obtained using the Green's Function method. Such a method can apply to subdomains that are completely uniform within. For example, subdomain 408 (in FIG. 4) has no structure within, and is thus uniform within. Similarly, subdomain 420 (in FIG. 4) is completely filled with a portion of uniform structure 106, The VSDD method applied to each of these subdomains may use the Green's Function method to solve for the residual source within each subdomain. These are solutions that have as their corresponding stimulus a single grid point stimulus. Hence, one can then solve for the entire subdomain by a single convolution, which can be done quickly using a fast-Fourier transform (FFT) in 2D or 3D. Also, the Green's function calculated is identical for all possible stimulus, and depends only on the frequency involved in the case of a steady-state equation, and the structure involved.

The equivalent VSDD problem for uniform subdomain 808 is set up as follows: subdomain 804 of the equivalent VSDD problem is equivalent to original subdomain 408; and extended subdomain 806 of the equivalent VSDD problem is equivalent to original extended subdomain 802. As in FIG. 5, the residual source is taken from subdomain 804. Extended subdomain 806 encloses subdomain 804. The residual field components will be solved for within all of extended subdomain 806. In addition, extended subdomain 806 encloses subdomain 804 by at least one pixel layer (or voxel layer in 3 dimensions). In this case, no absorbing boundary condition is needed as the Green function convolution implicitly provides for an infinite boundary, provided the infinite boundary condition Green function has been solved with minimal error.

As stated above, the Green's Function method applies to subdomains that consist of uniform space, and where a uniform grid is used, either because one is using finite-differencing, or finite-element with a structured mesh. The uniform grid requirement only holds for the local subdomain being solved; it is of no consequence if the grid is not uniform elsewhere in the entire problem domain. Also, a grid is still considered uniform as long as it has a uniform discretization in all dimensions even if it the discretization values for specific dimensions differ.

As the VSDD iteration proceeds, the same Green's Function can be re-used for a given subdomain without recalculation; a single solution iteration thus takes only two 2D or 3D FFT operations, plus other less expensive operations. The Green's Function solution is also a solution to the void space equivalent problem. Hence in instances where the border subdomains have uniform space (e.g. Subdomain 420 in FIG. 4), one may use the Green's Function approach to achieve the void space equivalent solution for the VSDD iteration.

The Green's Functions can be solved in some embodiments as follows. In 3D (2D), one expands a 2D (ID) plane (row) of variables to encompass all of k-space for some large periodicity, which in some embodiments is often 1000 or more periodic repeats in each dimension. For example, solving a 3D Green's function valid for, say, a region defined by the relations −50*dx≤x≤50*dx, −50*dy≤y≤50*dy, −50*dz≤z≤50*dz (here dx, dy, dz are the discretizations in each dimension) can entail solving for k-space on a Nx=1000, kx=nx*2π/(Nx*dx); −Nx/2<nx≤Nx/2, and ky=ny*2π/(Ny*dy); −Ny<ny≤Ny domain (here Nx, Ny are the number of k-space grid points to be used in the computation). In some embodiments, far more k-space grid points are used as compared to real-space grid points. In some embodiments, one can extend kx, ky to vary over an infinitely fine range for the exact solution (i.e. allow Nx→infinity), but this is not necessary. In some embodiments, extending to roughly 1000 can be sufficient, and may result in solution times on the order of tens of seconds or less on modern computers. For each point in this domain, one can then solve the eigenproblem that produces all modes and the kz vector in each case. Modes can be classified as forward or reverse propagating. One can use the Fourier-transform of a single variable at the origin to obtain a coefficient for each mode. Then, the modes can be swept, producing the Green's function.

It is advantageous to use this approach and solve for the exact discrete Green's function, as opposed to using an analytic expression, which can be very close to the discrete version, but may not be self-consistent with the rest of the solution. In some embodiments, it may be helpful to add a very small dissipative term to the background structure when solving the Green's Function, which might be thought of as a damping term that prevents a solution from becoming unstable by virtue of a resonance condition. Provided the value used is very small, the final solution vectors are not distorted, but the expressions involved are more stable. The final solution vector calculated for a given subdomain with the Green's Function method is added back to the solution vector for the entire domain. In some embodiments, the final solution calculated and added back will extend slightly beyond the regime in which the initial stimulus was provided.

Slab-Iteration Method

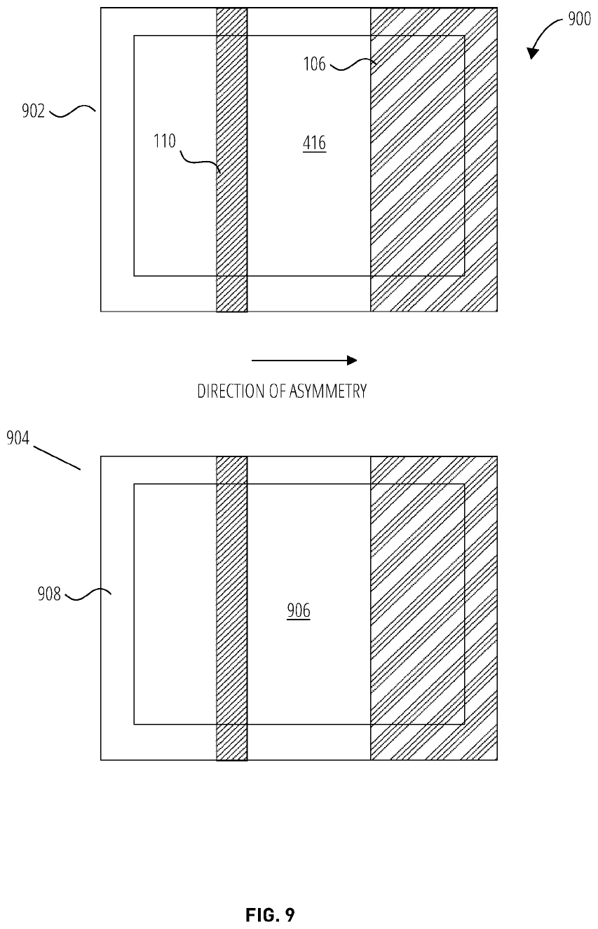

FIG. 9 illustrates solution of the void-space equivalent problem using the slab iteration method. In this case, the background structure within the subdomain has only a one-dimensional asymmetry, as indicated by the arrow in FIG. 9. An example of such a subdomain is subdomain 416 in FIG. 4.

In FIG. 9, the problem subdomain 416 has at least two structures of different types: structure 106 and structure 110. For example, in embodiments involving electrodynamics, the different types may be two different dielectric values. In some embodiments, the different types of properties can be other physical properties, such as optical properties, acoustic properties, mechanical properties or other physical properties of interest. While two “slabs” (i.e. Structure 106 and structure 110) are shown within subdomain 416, it is understood that there may be fewer or more slabs. Furthermore, the slabs may have identical material properties, or differ in their respective material properties.

The diagram 900 may be interpreted as either a 2D subdomain or a sectional view of a 3D subdomain.

A condition for the slab-iteration method is that asymmetry only exists in one dimension. In addition, within a subdomain (but not necessarily elsewhere) in most embodiments, the mesh is uniform, that is, have discrete translational symmetry in all dimension other than the asymmetric dimension. These are conditions required for the slab iteration solver to be used.

The equivalent VSDD problem 904 is set up as before. Subdomain 906 is equivalent to original subdomain 416, while extended subdomain 908 is equivalent to original extended subdomain 902. The residual source is within 806, and the residual field will be solved for within all of extended subdomain 908. In the slab-iteration method, there is no need for an absorbing boundary condition as the application of the slab-iteration method results in the problem being solved as if the boundary of extended subdomain 908 were infinite.

Similar to the Green's Function method, the slab-iteration method begins by calculating the modal coefficients in 2D or ID k-space, respectively, for a 3D or a 2D problem. Similar to the Green's Function method, a large region in k-space can be used. A set of coefficients is solved for in each of the distinct structural regions of the subdomain 906. Convolutions are no longer be used, however. Fourier transforms for the stimulus on each plane (row) of pixels for a 3D (2D) problem can be used. These modal coefficients can be advanced and iteratively reflected off of each structural interface. In almost all situations, convergence is be obtained. It is also possible to use the slab-iteration method even if there is nothing but a uniform structure, although the Green's Function method is more advantageous.

One challenge is that for some problems, such as embodiments involving electrodynamics, only stimulus components perpendicular to the direction of non-symmetry generate modal coefficients. To deal with the stimulus parallel to the direction of non-symmetry, one can use a Green's Function to project these components within each uniform region, and then re-apply the operator A, resulting in only perpendicular components to be solved.

While a slab iteration solution is an exact discrete solution for a subdomain, it also solves the void space equivalent problem. Already, between the slab-iteration and the Green's Function iteration, there are two iterations meeting the void space equivalent problem requirements and can be used on border subdomains without injecting uncorrectable error into the solution iterations. Similar to the Green's Function method, the residual field calculated for a subdomain (using the slab iteration method) is added back to the global solution vector, and often extends slightly beyond the region of the residual source used for the original subdomain.

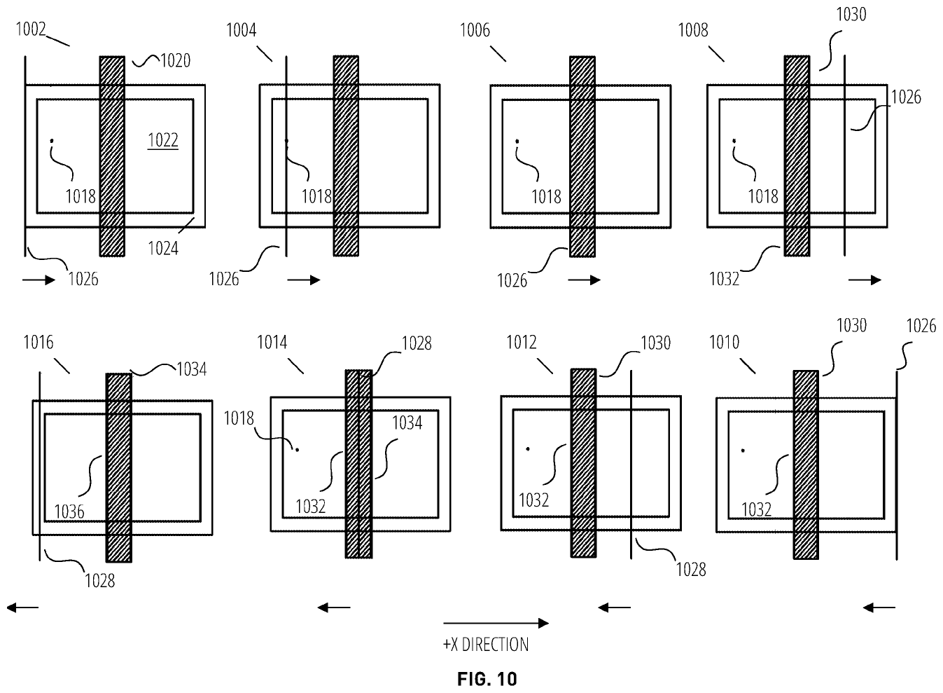

FIG. 10 illustrates an embodiment of the slab-iteration method in a series of panels, in which the direction of asymmetry is parallel to the X-axis The other two dimensions are continually symmetric. Subdomain 1022 contains a residual source 1018, while the field will be solved for within an extended subdomain 1024. Both subdomain 1022 and extended subdomain 1024 contain uniform structure 1020, which is implicitly assumed to extend infinitely in all directions other than the direction of asymmetry in the VSDD method, Hence, the slab iteration method provides a very good approximation to the exact void space equivalent While FIG. 10 illustrates the residual source 1018 localized at a point, it may extend throughout subdomain 1022.

If the overall simulation dimension is in two dimensions or three dimensions, the lateral k-space then has dimensionality of one dimension or two dimensions, respectively. The basic approach is to solve for the forward and reverse propagating modes in x for each lateral k-vector, as shown in snapshots panel 1002-panel 1016. A modal surface 1026 sweeps across the simulation domain in the direction shown by the arrow. In the first sweep, in the +x direction, only the forward modes are to be swept. At each pixel layer or voxel layer in 3 dimensions), the field is generated and an inverse FFT is taken to project the fields back from k-space. The fields thus derived are accumulated within extended subdomain 1024.

In panel 1004, the modal surface 1026 encounters residual source 1018. As an example, in the case of Maxwell's equations, any possible current configuration of the four current components lateral to the x direction can be projected into forward and reverse modes. (J and Jₕ). As mentioned before, the two normal current components can be converted into lateral components by convolution; the components are convolved with a Green function in each uniform region, and the resulting field has the A operator applied, leaving only lateral current on the border. The rest applies to any general physical equation. In panel 1004, the forward modes generated by residual source 1018 are added to the modal surface. The modal surface 1026 is continually propagated, and when the modal surface 1026 reaches the uniform structure 1020 in panel 1006, the transmission and reflection across the interface of structure 1020 is calculated. In panel 1008, the reflected surface 1030 and surface 1032 are created on the right and left borders of the structure 1020 as the forward propagating modal surface 1026 is now past the uniform structure 1020. In panel 1010, modal surface 1026 has now reached the end of the extended subdomain 1024. The new surface 1030 and surface 1032 contain the set of reverse propagating modal amplitudes in k-space to be added to the final solution due to the reflections on this interface.

Now a new set of reverse propagating modal coefficients must be swept in the −X direction, which is shown in panel 1010 to panel 1016. In panel 1014, the reverse propagating modal surface 1028 is swept into the region occupied by structure 1020, in the process having the previously reflected reverse surface 1030 added to it as it passed through. The reflected surface 1034, which now contains forward propagating modes, is also created. Finally, in panel 1016, reverse propagating modal surface 1028 has been swept all the way across the extended subdomain 1024. The new modal surface 1036 with reflected modes on the interior of the structure 1020 is created, while surface 1032 has been added to modal surface 1028 as it passed through and is thus also eliminated. But the original residual source 1018 is wholly solved for. The process can continue, with first forward and reverse modal surfaces propagating across the slab-iteration domain, until the norm of the modal coefficient surface is below a pre-selected threshold.

In an example where there is either one or no structural interface within the extended subdomain 1024, then a single forward and reverse sweep will always result in an exact solution.

There are variations of the VSDD method.

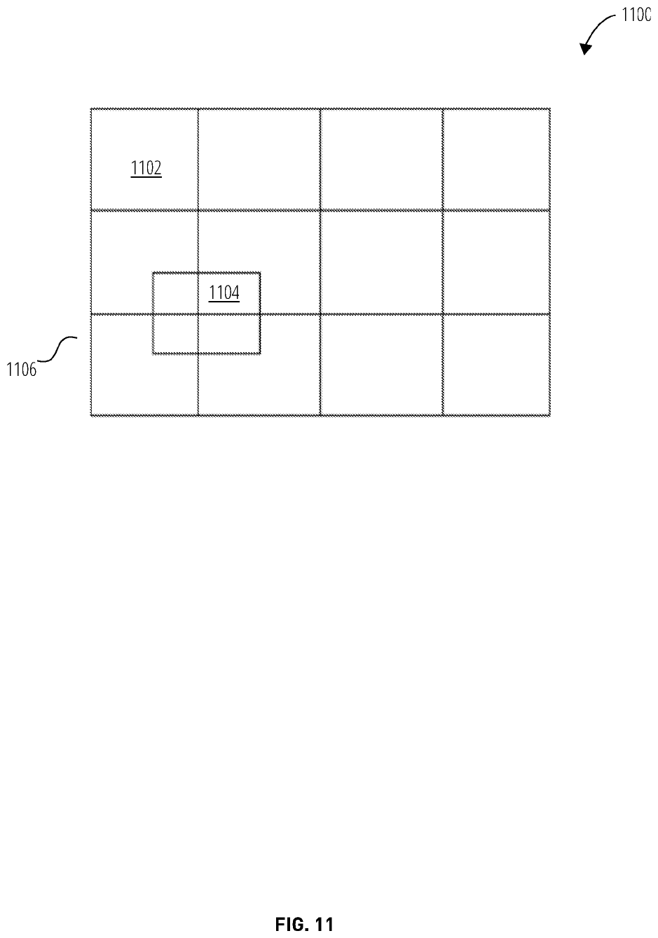

For example, FIG. 11 illustrates adaptive meshing in accordance with one embodiment. For example, schematic diagram adaptive meshing 1100 illustrates a selection of subdomains where adaptive meshing is present. In FIG. 11, 1104 indicates a region with a higher mesh density than region 1102. While FIG. 11 is not to scale, the subdomains within region 1104 are about one-fourth the size of the subdomain in region 1102. The partitioning of the full domain 1106 into subdomains can proceed independent of the location of the region with higher mesh density.

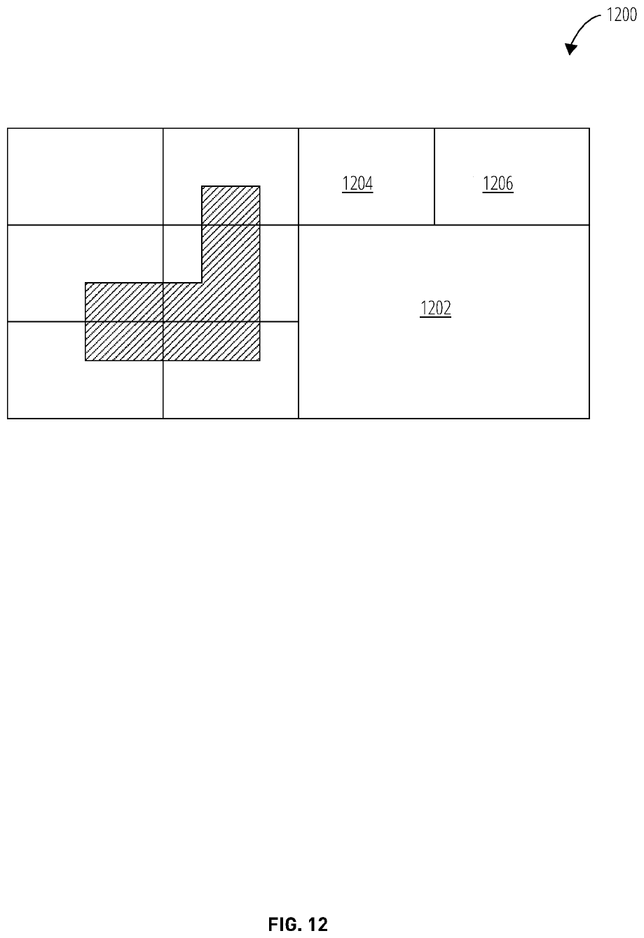

In another variation, one or more subdomains can be combined into a single large subdomain. FIG. 12 illustrates how, in some embodiments, such as cases of large areas of uniform space or regions with only 1D asymmetry, a plurality of subdomains can be combined into an amalgamated subdomain 1202. On the other hand, subdomain 1204 and subdomain 1206 remain unmodified.

In some embodiments, amalgamated subdomain 1202 can be solved with a Green's Function approach or a slab iteration approach with significantly increased speed. In some embodiments, one can simply select subdomains for amalgamation in a manner that ignores the existence of the adaptive meshed regions, as shown in FIG. 12. It is possible to adjust the size of some of the subdomains to make the computational process more uniform. However, the existence of a change in mesh density does not change the requirement of solving the equivalent void space problem for each subdomain. At borders between the region with a finer mesh and a coarser mesh, the underlying finite difference expression can be recast to simply utilize a volumetric approximation of the neighboring solution vector instead of a single grid point value.

In some simulation embodiments, there are extensive areas that are either uniform space, or are a series of structures with asymmetry only in one dimension (such regions might be used with the slab iteration method). In embodiments where these regions extend over what otherwise would be several independent subdomains, one can combine those subdomains into a single amalgamated subdomain, thereby greatly improving simulation performance, since the subdomain solve methods used for the slab iteration method and the Green's function method often scale in a sublinear manner as a function of the subdomain size. That is to say, it will not take twice (2×) the amount of time with the Green's function or slab iteration method to solve a subdomain with twice (2×) the amount of grid points. Further, since the invariant A*X=B is maintained within this region, it may not even be necessary to store X, B or δB within this region, thus significantly decreasing memory requirements, except for embodiments in which the solution vector X is needed as an output in this region.

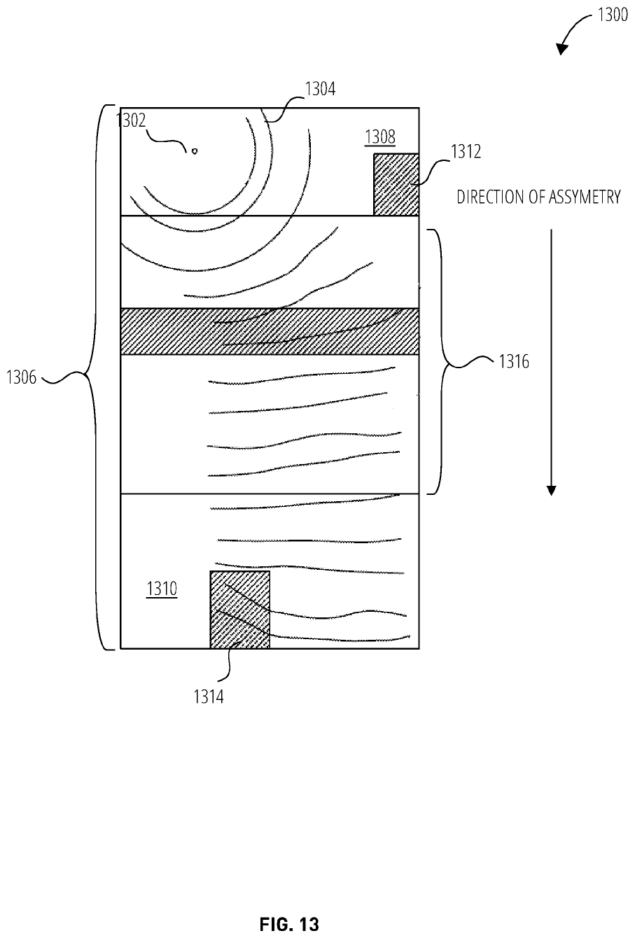

In another variation, FIG. 13 illustrates how two regions, each with a distinct structure can be combined into a single VSDD simulation by using a slab iteration or Green's Function method in a regions intervening between the two regions. Source 1302 emits excitation 1304, which extends throughout the full domain 1306. Within region 1308 and region 1310, there are non-symmetric structures (i.e. Structure 1312 and structure 1314). Therefore, neither region 1308 nor region 1310 are amenable either the Green's Function method or the slab-iteration. These regions may be large and may be divided into multiple subdomains. The region 1316, however, which may be far larger than a typical subdomain, has only 1d asymmetry, in the direction indicated by the arrow. Region 1316 can be treated as a single large subdomain and the slab-iteration used. If, on the other hand, the structure in region 1316 were uniform, then the Green's Function method may be used.

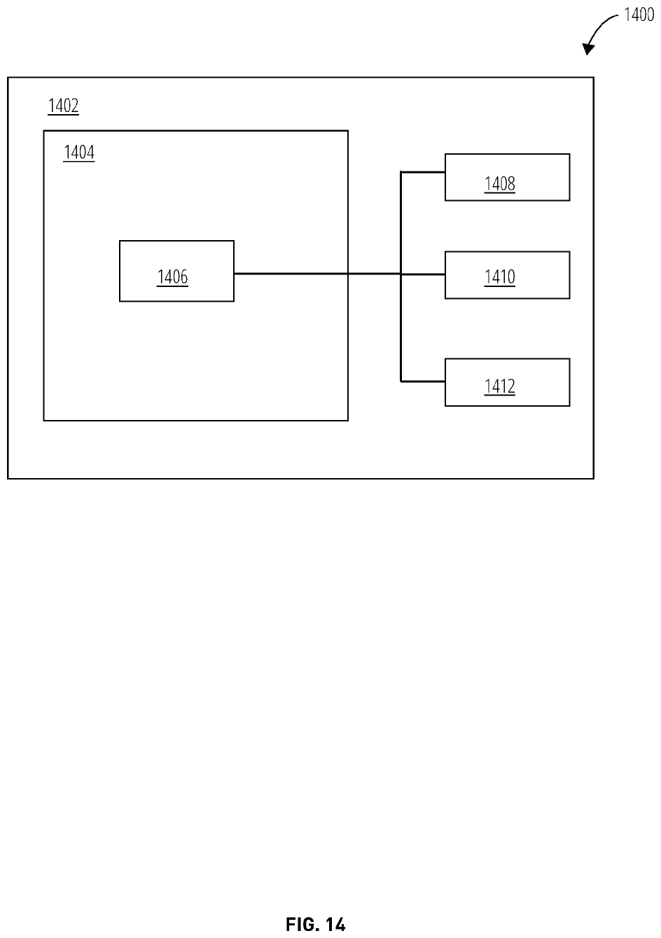

FIG. 14 illustrates a block diagram of an embodiment of a system 1400 for implementing the VSDD method on a computer. The system 1400 may comprise a computing unit 1402 (or a computing system). The computing unit 1402 can comprise memory 1404, one or more application programs or modules 1406, a processing unit 1408 and a user interface 1410. The computing unit 1402 is only one example of a computing environment and is not intended to suggest any limitation as to the scope of use or functionality of the VSDD method.

The memory 1404 can store the one or more application programs (or program modules) 1406 containing computer-executable instructions, executed by the computing unit 1402 for implementing the VSDD method. The memory 1404 can include a number of modules 1406 that enable the method outlined in FIG. 2 and FIG. 6.

Although the computing unit 1402 is shown as having a general memory 1404, the computing unit 1402 may also include different types of computer readable media. By way of example, and not limitation, computer readable media may comprise computer storage media. The computing system memory 1404 may include computer storage media in the form of volatile and/or nonvolatile memory such as a read only memory (ROM) and random access memory (RAM). A basic input/output system (BIOS), containing the basic routines that help to transfer information between elements within the computing unit, such as during start-up, is typically stored in ROM. The RAM typically contains data and/or program modules that are immediately accessible to and/or presently being operated on by the processing unit. By way of example, and not limitation, the computing unit includes an operating system, application programs, other program modules, and program data. The components shown in the memory 1404 may also be included in other removable/non-removable, volatile/nonvolatile computer storage media or they may be implemented in the computing unit through application program interface (“API”), which may reside on a separate computing unit connected through a computer system or network. For example only, a hard disk drive may read from or write to non-removable, nonvolatile magnetic media, a magnetic disk drive may read from or write to a removable, non-volatile magnetic disk, and an optical disk drive may read from or write to a removable, nonvolatile optical disk such as a CD ROM or other optical media. Other removable/non-removable, volatile/non-volatile computer storage media that can be used in the exemplary operating environment may include, but are not limited to, magnetic tape cassettes, flash memory cards, digital versatile disks, digital video tape, solid state RAM, solid state ROM, and the like. The drives and their associated computer storage media discussed above provide storage of computer readable instructions, data structures, program modules and other data for the computing unit. A user may enter commands and information into the computing unit 1402 through a user interface 1410, which may include input devices such as a keyboard and pointing device (e.g. a mouse, trackball, touch pad, etc.). Input devices may include a microphone, joystick, satellite dish, scanner, or the like. These and other input devices are often connected to the processing unit 1408 through a system bus, but may be connected by other interface and bus structures, such as a parallel port or a universal serial bus (USB). A monitor or other type of display device may be connected to the system bus via an interface 1412, such as a video interface. A graphical user interface (“GUI”) may also be used with the interface 1412 to receive instructions from the user interface 1410 and transmit instructions to the processing unit 1408. In addition to the monitor, computers may also include other peripheral output devices such as speakers and printer, which may be connected through an output peripheral interface. Although many other internal components of the computing unit 1402 are not shown, those of ordinary skill in the art will appreciate that such components and their interconnection are well known.

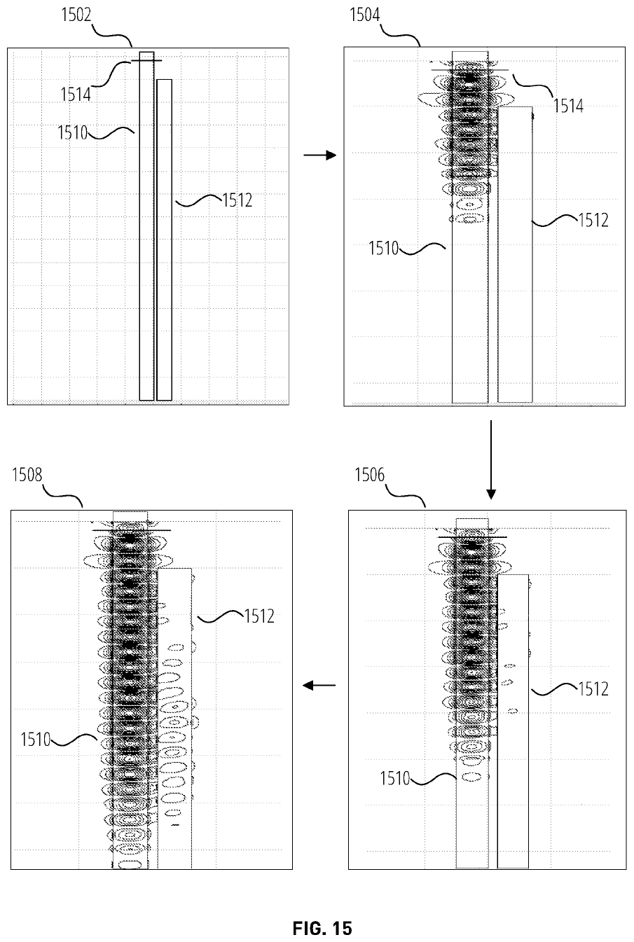

FIG. 15 illustrates a simulation of an electromagnetic field in the presence of two waveguides (waveguide 1510 and waveguide 1512), with a source 1514. Each waveguide is 500 nm in width and 200 nm in height Si waveguides. The waveguides are separated by 150 nm. The waveguides are made of silicon and clad in silicon dioxide (SiO₂). The configuration illustrated in panel 1502 is often used in integrated optics.

In FIG. 15, a guided waveguide mode is launched by source 1514 in waveguide 1510, at a frequency corresponding to a free space wavelength of 1.55 m. That is to say, the frequency of this source 1514 is roughly 192 THz, which is in the near-infrared regime. The grid is 300×200×400 pixels, with a discretization of 0.02 μm/pixel, resulting in approximately 375 subdomains. The simulation was conducted using parallel processing with 2 GPU cards using the VSDD method. A combination of the time-stop method, the Green function method, and steady-state with ABC method was used to solve for the subdomains in this iteration.

Panel 1504 is shown after approximately 5 minutes of runtime. The guided mode has begun to propagate down waveguide 1510, but has not yet coupled into waveguide 1512.

Panel 1506 is shown after approximately 10 minutes of runtime. The guided mode has now propagated significantly farther down waveguide 1510, but has still not yet significantly coupled to waveguide 1512.

Panel 1508 is shown after 15 minutes of runtime. Now a substantial portion of the guided mode that was originally in waveguide 1510 has coupled into waveguide 1512. The simulation is not yet fully converged, but already important information about the behavior of the system can be determined.

As shown in the progression of panel 1502 to panel 1508, in the process of the convergence of the VSDD algorithm, an initial current source 1514 is found to launch a guided mode in waveguide 1510, which then couples via directional coupling into waveguide 1512.

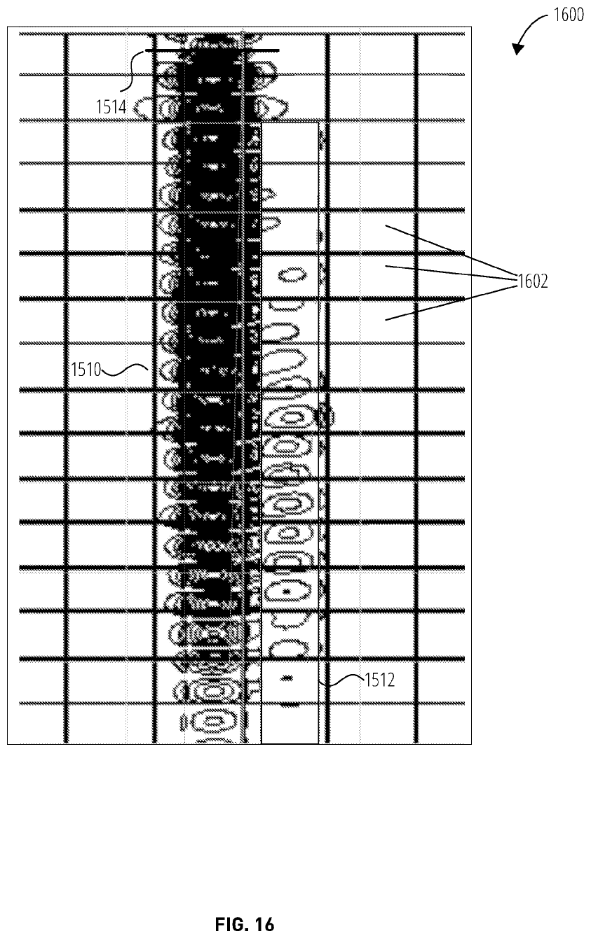

FIG. 16 illustrates the simulation of the configuration shown in FIG. 15 after 20 minutes of run-time. The simulation shown is at about 20 overall iterations, with 4000 subdomain solves—that is, an average of approximately 200 subdomain solves per iteration. The runtime is faster when the simulation is run on a cluster. In FIG. 16, the black lines indicate the locations of subdomains 1602. One may note in FIG. 15 that no apparent evidence of the subdomain locations is present in the field evolution, highlighting the success of this method in providing a globally correct solution.

While the present method has been described in connection with presently preferred embodiments, it will be understood by those skilled in the art that it is not intended to limit the invention to those embodiments. It is therefore, contemplated that various alternative embodiments and modifications may be made to the disclosed embodiments without departing from the spirit and scope of the invention defined by the appended claims and equivalents thereof.

What is claimed is:

1. A computer implemented method for determining a field generated from a source, the field interacting with one or more structures, the method comprising:
providing a simulation space comprising a domain that contains the source and the one or more structures;
simulating, by a computer, the field within the domain based at least in part on an operator acting on the field, with simulating further comprising:
dividing the domain into a plurality of subdomains;
designating a first iteration of the field;
determining a global residual source based on the operator acting on the first iteration of the field throughout the domain;
iteratively solving for the field by solving for residual field behavior in a subset of the subdomains at each iteration;
wherein solving for residual field behavior in a subdomain of the subset comprises:
the operator acting on a local residual field within an extended subdomain around the subdomain; and
where the subdomain comprises a structure, extending a boundary of the structure located at a boundary of the extended subdomain, beyond the boundary of the extended subdomain to a second extended subdomain.

2. The computer implemented method of claim 1, wherein:
the operator is modified to include a loss; and
simulating further comprises one or more convergence cycles in which the modified operator acts on a modified residual field.

3. The method of claim 1, wherein simulating further comprises:
using a Green's Function method to solve for the local residual field when the subdomain is filled with uniform space;
using a slab-iteration method to solve for the local residual field when the subdomain has a one-dimensional asymmetry; and
using either a steady-state method with absorbing boundary conditions or a time-stop method, to solve for the local residual field when the subdomain is neither filled with uniform space nor has the one-dimensional asymmetry.

4. The method of claim 3, wherein simulating further comprises applying the time-stop method when the subdomain is a border subdomain and applying the steady-state method with absorbing boundary conditions when the subdomain is an interior subdomain.

5. The computer-implemented method of claim 1, wherein the field is an electromagnetic field, a fluid flow field, a heat conduction field, a diffusion field or an electrostatic field.

6. The computer-implemented method of claim 1, wherein the field is an electromagnetic field that satisfies the modified Maxwell's equation:
$$( \begin{matrix}- i ωɛ + σ & {∇}^{⟶} \times \\ - {∇}^{⟶} \times & - i ωμ + {σ}_{h}\end{matrix} ) ( \begin{matrix}{E}^{⟶} \\ {H}^{⟶}\end{matrix} ) = ( \begin{matrix}{{J}^{⟶}}_{s} \\ {{J}^{⟶}}_{hs}\end{matrix} )$$
and the one or more structures comprises at least one waveguide or at least one transmission line.

7. The method of claim 1, wherein simulating further comprises the steps of:
a) determining a new source based on operation of the operator on a current iteration of the field;
b) determining the global residual source based on a difference between the new source and the source;
c) ending simulation and setting the field equal to the current iteration of the field, if a magnitude of the global residual source is less than a first pre-set threshold;
d) if the magnitude of the global residual source is greater than the first pre-set threshold, scanning the plurality of subdomains to determine the subset of subdomains, each subdomain within the subset having a local residual source magnitude greater than a second pre-set threshold;
e) constructing the extended subdomain around the subdomain;
f) solving for a local residual field within the extended subdomain;
g) adding all of the local residual fields from the subset to provide a new estimate of the field;
h) setting the current iteration of the field equal to the new estimate of the field; and
i) repeating steps (a) through (h) until the magnitude of the residual source is less than the first pre-set threshold.

8. A non-transitory computer storage medium encoded with computer program instructions for determining a field generated from a source, the field interacting with one or more structures, with the computer program instructions when executed by one or more computers cause the one or more computers to:
provide a simulation space comprising a domain that contains the source and the one or more structures;
simulate the field within the domain based at least in part on an operator acting on the field;
divide the domain into a plurality of subdomains;
designate a first iteration of the field;
determine a residual source based on the operator acting on the first iteration of the field throughout the domain;
iteratively solve for the field by solving for residual field behavior in a subset of the subdomains;
wherein solving for residual field behavior in a subdomain of the subset comprises:
the operator acting on the residual field within an extended subdomain around the subdomain; and
where the subdomain comprises a structure, extending a boundary of the structure located at a boundary of the extended subdomain, beyond the boundary of the extended subdomain to a second extended subdomain.

9. The non-transitory computer storage medium of claim 8, wherein:
the operator acting on the residual field is modified to include a loss; and
causing the computer to simulate the field within the domain comprises causing the computer to simulate one or more convergence cycles in which the modified operator acts on a modified residual field.

10. The non-transitory computer storage medium of claim 8, wherein:
causing the computer to simulate the field within the domain comprises causing the computer to:
use a Green's Function method to solve for the residual field when the subdomain is filled with uniform space;
use a slab-iteration method to solve for the residual field when the subdomain has a one-dimensional asymmetry; and
use either a steady-state method with absorbing boundary conditions; or a time-stop method, to solve for the residual field when the subdomain is neither filled with uniform space nor having a one-dimensional asymmetry.

11. The non-transitory computer storage medium of claim 10, wherein causing the computer to simulate the field within the domain comprises causing the computer to:
apply the time-stop method when the subdomain is a border subdomain and apply the steady-state method with absorbing boundary conditions when the subdomain is an interior subdomain.

12. The non-transitory computer storage medium of claim 8, wherein the field is an electromagnetic field, a fluid flow field, a heat conduction field, a diffusion field or an electrostatic field.

13. The non-transitory computer storage medium of claim 8, wherein the field is an electromagnetic field that satisfies the modified Maxwell's equation:
$$( \begin{matrix}- i ωɛ + σ & {∇}^{⟶} \times \\ - {∇}^{⟶} \times & - i ωμ + {σ}_{h}\end{matrix} ) ( \begin{matrix}{E}^{⟶} \\ {H}^{⟶}\end{matrix} ) = ( \begin{matrix}{{J}^{⟶}}_{s} \\ {{J}^{⟶}}_{hs}\end{matrix} )$$
and the one or more structures comprises at least one waveguide or at least one transmission line.

14. The non-transitory computer storage medium of claim 8, wherein causing the computer to simulate the field within the domain comprises causing the computer to:
a) determine a new source based on operation of the operator on a current iteration of the field;
b) determine the global residual source based on a difference between the new source and the source;
c) end simulation and setting the field equal to the current iteration of the field, if a magnitude of the global residual source is less than a first pre-set threshold;
d) if the magnitude of the global residual source is greater than the first pre-set threshold, scan the plurality of subdomains to determine the subset of subdomains, each subdomain within the subset having a local residual source magnitude greater than a second pre-set threshold;
e) construct the extended subdomain around the subdomain;
f) solve for a local residual field within the extended subdomain;
g) add all of the local residual fields from the subset to provide a new estimate of the field;
h) set the current iteration of the field equal to the new estimate of the field; and
i) repeat steps (a) through (h) until the magnitude of the residual source is less than the first pre-set threshold.

15. A computer system for simulating a field generated from a source, the field interacting with one or more structures, the system being configured to:
provide a simulation space comprising a domain that contains the source and the one or more structures;
simulate the field within the domain based at least in part on an operator acting on the field;
divide the domain into a plurality of subdomains;
designate a first iteration of the field;
determine a residual source based on the operator acting on the first iteration of the field throughout the domain;
iteratively solve for the field by solving for residual field behavior in a subset of the subdomains;
wherein solving for residual field behavior in a subdomain of the subset comprises:
the operator acting on the residual field within an extended subdomain around the subdomain; and
where the subdomain comprises a structure, extending a boundary of the structure located at a boundary of the extended subdomain, beyond the boundary of the extended subdomain to a second extended subdomain.

16. The computer system of claim 15, wherein when simulating the field, the system is further configured to:
modify the operator to include a loss; and
run one or more convergence cycles in which the modified operator acts on a modified residual field.

17. The computer system of claim 15, wherein when simulating the field, the system is further configured to:
use a Green's Function method to solve for the local residual field when the subdomain is filled with uniform space;
use a slab-iteration method to solve for the local residual field when the subdomain has a one-dimensional asymmetry; and
use either a steady-state method with absorbing boundary conditions or a time-stop method, to solve for the local residual field when the subdomain is neither filled with uniform space nor has the one-dimensional asymmetry.

18. The computer system of claim 17, wherein when simulating the field, the system is further configured to:
apply the time-stop method when the subdomain is a border subdomain; and
apply the steady-state method with absorbing boundary conditions when the subdomain is an interior subdomain.

19. The computer system of claim 15, wherein the field is an electromagnetic field that satisfies the modified Maxwell's equation:
$$( \begin{matrix}- i ωɛ + σ & {∇}^{⟶} \times \\ - {∇}^{⟶} \times & - i ωμ + {σ}_{h}\end{matrix} ) ( \begin{matrix}{E}^{⟶} \\ {H}^{⟶}\end{matrix} ) = ( \begin{matrix}{{J}^{⟶}}_{s} \\ {{J}^{⟶}}_{hs}\end{matrix} )$$
and the one or more structures comprises at least one waveguide or at least one transmission line.

20. The computer system of claim 15, wherein when simulating the field, the system is further configured to:
a) determine a new source based on operation of the operator on a current iteration of the field;
b) determine the global residual source based on a difference between the new source and the source;
c) end simulation and setting the field equal to the current iteration of the field, if a magnitude of the global residual source is less than a first pre-set threshold;
d) if the magnitude of the global residual source is greater than the first pre-set threshold, scan the plurality of subdomains to determine the subset of subdomains, each subdomain within the subset having a local residual source magnitude greater than a second pre-set threshold;
e) construct the extended subdomain around the subdomain;
f) solve for a local residual field within the extended subdomain;
g) add all of the local residual fields from the subset to provide a new estimate of the field;
h) set the current iteration of the field equal to the new estimate of the field; and
i) repeat steps (a) through (h) until the magnitude of the residual source is less than the first pre-set threshold.
